(19) United States
(12) Patent Application Publication
(10) Pub. No.: US 2026/0344312 A1
(43) Pub. Date: Oct. 29, 2026

(54) LASER PROCESSING DEVICE, AND LASER PROCESSING METHOD

(71) Applicant: HAMAMATSU PHOTONICS K.K., Hamamatsu-shi, Shizuoka (JP)

(72) Inventors: Takeshi SAKAMOTO, Hamamatsu-shi, Shizuoka (JP); Takafumi OGIWARA, Hamamatsu-shi, Shizuoka (JP); Masaki OYAIZU, Hamamatsu-shi, Shizuoka (JP)

(73) Assignee: HAMAMATSU PHOTONICS K.K., Hamamatsu-shi, Shizuoka (JP)

(21) Appl. No.: 19/103,969

(22) PCT Filed: Aug. 8, 2023
(86) PCT No.: PCT/JP2023/028946

§ 371 Date: Feb. 14, 2025

(30) Foreign Application Priority Data
Sep. 13, 2022 (JP) 2022-145550

(51) Int. Cl. H10P 34/40; B23K 26/08; B23K 26/352

(52) U.S. Cl. CPC H10P 34/40; B23K 26/083; B23K 26/352

(57) ABSTRACT

A laser processing apparatus includes: a support unit; a light source; a spatial light modulator; a converging unit; and a drive unit and a control unit. The control unit causes the spatial light modulator to display a modulation pattern including a trefoil aberration pattern so that a beam shape of laser light at a converging spot becomes a beam shape that includes a central portion, and a first extension portion, a second extension portion, and a third extension portion extending radially from the central portion, and has the highest intensity at the central portion. The control unit causes the drive unit to drive at least one of the support unit and the converging unit so that the converging spot is moved relatively along a line.

### TECHNICAL FIELD

The present disclosure relates to a laser processing apparatus and a laser processing method.

BACKGROUND ART

There is known a laser processing apparatus including a support unit that supports an object, a light source that emits laser light, a spatial light modulator that modulates the laser light emitted from the light source, a converging unit that converges the laser light modulated by the spatial light modulator to the object, and an image transfer unit that transfers an image of the laser light in the spatial light modulator to an entrance pupil plane of the converging unit (for example, refer to Patent Literature 1).

### CITATION LIST

### Patent Literature

Patent Literature 1: Japanese Unexamined Patent Publication No. 2011-51011

### SUMMARY OF INVENTION

### Technical Problem

The above-described laser processing apparatus can form a modified region and a fracture in the object. Formation of the modified region and the fracture is applicable to various kinds of processing such as dicing processing of dividing the object into a plurality of chips, and a trimming processing of removing an unnecessary portion from the object.

An object of the present disclosure is to provide a laser processing apparatus and a laser processing method capable of forming an appropriate modified region and an appropriate fracture in an object in correspondence with processing.

### Solution to Problem

A laser processing apparatus according to an aspect of the present disclosure is [1] “A laser processing apparatus including: a support unit configured to support an object; a light source configured to emit laser light; a spatial light modulator configured to modulate the laser light emitted from the light source by displaying a modulation pattern; a converging unit configured to converge the laser light modulated by the spatial light modulator to the object; a drive unit configured to drive at least one of the support unit and the converging unit; and a control unit configured to control at least the spatial light modulator and the drive unit. The control unit causes the spatial light modulator to display a modulation pattern including a trefoil aberration pattern so that a beam shape of the laser light at a converging spot of the laser light becomes a beam shape that includes a central portion, and a first extension portion, a second extension portion, and a third extension portion extending radially from the central portion, and has the highest intensity at the central portion, and causes the drive unit to drive at least one of the support unit and the converging unit so that the converging spot is moved relatively along a line set to the object in a state in which the spatial light modulator is caused to display the modulation pattern including the trefoil aberration pattern”.

In the laser processing apparatus described in [1], in a state in which the beam shape of the laser light at the converging spot includes the central portion, and the first extension portion, the second extension portion, and the third extension portion extending radially from the central portion, and has the highest intensity at the central portion, the converging spot can be moved relatively along the line set to the object. At this time, it is possible to adjust a state of at least one of a modified region and a fracture formed in the object by adjusting a direction of the beam shape with respect to the line, or the like. As a result, according to the laser processing apparatus described in [1], it is possible to form an appropriate modified region and an appropriate fracture in the object in correspondence with processing.

The laser processing apparatus according to the aspect of the present disclosure may be [2] “The laser processing apparatus according to [1], wherein in a case of forming a modified region in the object along the line, and forming a fracture in the object from the modified region along a first plane parallel to both an incident direction of the laser light and an extension direction of the line, the control unit causes the spatial light modulator to display the modulation pattern including the trefoil aberration pattern so that the first extension portion is located on the line, the second extension portion is located on one side with respect to the line, and the third extension portion is located on the other side with respect to the line”. According to the laser processing apparatus described in [2], a width of a fracture in the incident direction of the laser light can be further reduced, for example, as compared with a case where the modulation pattern does not include the trefoil aberration pattern.

The laser processing apparatus according to the aspect of the present disclosure may be [3] “The laser processing apparatus according to [2], wherein the control unit causes the spatial light modulator to display the modulation pattern including the trefoil aberration pattern so that the first extension portion is located on a front side of a direction in which the converging spot is moved relatively along the line, and the second extension portion and the third extension portion are located on a rear side of the direction”. According to the laser processing apparatus described in [3], it is possible to reduce not only the width of the fracture in the incident direction of the laser light but also the width of the modified region in the incident direction of the laser light. In addition, it is possible to reliably prevent the fracture from meandering with respect to the line.

The laser processing apparatus according to the aspect of the present disclosure may be [4] “The laser processing apparatus according to [3], wherein in a case of relatively moving the converging spot along each of a first line and a second line set to the object as the line, when a direction in which the converging spot is moved relatively along the first line and a direction in which the converging spot is moved relatively along the second line are different from each other, the control unit switches a direction of the modulation pattern including the trefoil aberration pattern so that the first extension portion is located on a front side of the direction in which the converging spot is moved relatively along each of the first line and the second line, and the second extension portion and the third extension portion are located on a rear side of the direction”. According to the laser processing apparatus described in [4], even in a case where a direction in which the converging spot is moved relatively along the first line and a direction in which the converging spot is moved relatively along the second line are different from each other, it is possible to easily and reliably realize a state in which the first extension portion is located on a front side of the direction in which the converging spot is moved relatively along each of the first line and the second line, and the second extension portion and the third extension portion are located on a rear side of the direction.

The laser processing apparatus according to the aspect of the present disclosure may be [5] “The laser processing apparatus according to any one of [2] to [4], wherein the control unit causes the spatial light modulator to display the modulation pattern including the trefoil aberration pattern with a first trefoil aberration intensity in a case where a width of at least one of the modified region and the fracture in the incident direction of the laser light is set to a first width, and causes the spatial light modulator to display the modulation pattern including the trefoil aberration pattern with a second trefoil aberration intensity stronger than the first trefoil aberration intensity in a case where the width of the at least one of the modified region and the fracture is set to a second width smaller than the first width”. According to the laser processing apparatus described in [5], it is possible to set the width of at least one of the modified region and the fracture in the incident direction of the laser light to an appropriate width in correspondence with processing.

The laser processing apparatus according to the aspect of the present disclosure may be [6] “The laser processing apparatus according to [1], wherein in a case of forming a modified region in the object along the line, and forming a fracture in the object from the modified region along a second plane oblique to a first plane parallel to both an incident direction of the laser light and an extension direction of the line, when the second plane is oblique so that a region on a side opposite to an incident side of the laser light is located on one side in a direction orthogonal to the first plane, the control unit causes the spatial light modulator to display the modulation pattern including the trefoil aberration pattern so that the first extension portion is located on the one side with respect to the line, and the second extension portion and the third extension portion are located on the other side with respect to the line”. According to the laser processing apparatus described in [6], it is possible to cause a fracture extending from the modified region to be oblique to a desired side.

The laser processing apparatus according to the aspect of the present disclosure may be [7] “The laser processing apparatus according to [6], wherein in a case of relatively moving the converging spot along each of a first line and a second line set to the object as the line, when a direction in which the converging spot is moved relatively along the first line and a direction in which the converging spot is moved relatively along the second line are different from each other, the control unit switches a direction of the modulation pattern including the trefoil aberration pattern so that the first extension portion is located on one side with respect to each of the first line and the second line, and the second extension portion and the third extension portion are located on the other side with respect to each of the first line and the second line”. According to the laser processing apparatus described in [7], even in a case where a direction in which the converging spot is moved relatively along the first line and a direction in which the converging spot is moved relatively along the second line are different from each other, it is possible to easily and reliably realize a state in which the first extension portion is located on one side with respect to each of the first line and the second line, and the second extension portion and the third extension portion are located on the other side with respect to each of the first line and the second line.

The laser processing apparatus according to the aspect of the present disclosure may be [8] “The laser processing apparatus according to [6] or [7], wherein the control unit causes the spatial light modulator to display the modulation pattern including the trefoil aberration pattern with a first trefoil aberration intensity in a case where an angle between the first plane and the second plane is set to a first angle, and causes the spatial light modulator to display the modulation pattern including the trefoil aberration pattern with a second trefoil aberration intensity stronger than the first trefoil aberration intensity in a case where the angle is set to a second angle larger than the first angle”. According to the laser processing apparatus described in [8], it is possible to set an oblique angle of the fracture extending from the modified region to an appropriate angle in correspondence with processing.

A laser processing method of another aspect of the present disclosure is [9] “A laser processing method that is carried out in a laser processing apparatus including a support unit configured to support an object, a light source configured to emit laser light, a spatial light modulator configured to modulate the laser light emitted from the light source by displaying a modulation pattern, a converging unit configured to converge the laser light modulated by the spatial light modulator to the object, and a drive unit configured to drive at least one of the support unit and the converging unit, the method including: a process of causing the spatial light modulator to display a modulation pattern including a trefoil aberration pattern so that a beam shape of the laser light at a converging spot of the laser light becomes a beam shape that includes a central portion, and a first extension portion, a second extension portion, and a third extension portion extending radially from the central portion, and has the highest intensity at the central portion; and a process of causing the drive unit to drive at least one of the support unit and the converging unit so that the converging spot is moved relatively along a line set to the object in a state in which the spatial light modulator is caused to display the modulation pattern including the trefoil aberration pattern”.

In the laser processing method described in [9], in a state in which the beam shape of the laser light at the converging spot includes the central portion, and the first extension portion, the second extension portion, and the third extension portion extending radially from the central portion, and has the highest intensity at the central portion, the converging spot can be moved relatively along the line set to the object. At this time, it is possible to adjust a state of at least one of a modified region and a fracture formed in the object by adjusting a direction of the beam shape with respect to the line, or the like. As a result, according to the laser processing method described in [9], it is possible to form an appropriate modified region and an appropriate fracture in the object in correspondence with processing.

### Advantageous Effects of Invention

According to the present disclosure, it is possible to provide a laser processing apparatus and a laser processing method capable of forming an appropriate modified region and an appropriate fracture in an object in correspondence with processing.

### BRIEF DESCRIPTION OF DRAWINGS

FIG. 1 is a view illustrating a configuration of a laser processing apparatus of an embodiment.

FIG. 2 is a view illustrating a configuration of an irradiation unit shown in FIG. 1.

FIG. 3 is a view illustrating a 4f lens unit shown in FIG. 2.

FIG. 4 is a view illustrating a spatial light modulator shown in FIG. 2.

FIG. 5 is a view illustrating an example of a trefoil aberration pattern.

FIG. 6 is a view illustrating an example of a converging state of laser light and an example of a beam shape of the laser light in a converging spot.

FIG. 7 is a view illustrating an example of a beam shape of laser light for every trefoil aberration intensity.

FIG. 8 is a view illustrating an example of a beam shape of laser light modulated by a trefoil aberration pattern.

FIG. 9 is a view illustrating an example of a beam shape of laser light modulated by the trefoil aberration pattern and an astigmatism pattern.

FIG. 10 is a view illustrating an example of a beam shape of laser light modulated by the trefoil aberration pattern, the astigmatism pattern, and a spherical aberration pattern.

FIG. 11 is a view illustrating an example of a beam shape of laser light modulated by the trefoil aberration pattern.

FIG. 12 is a view illustrating an example of a converging state of laser light and an example of a damage due to leaked light of laser light.

FIG. 13 is a view illustrating a first example of a cut-out surface of an object for each laser processing condition.

FIG. 14 is a view illustrating the first example of the cut-out surface of the object for each laser processing condition.

FIG. 15 is a view illustrating a relationship between the trefoil aberration intensity, and a width of each of a modified region and a fracture.

FIG. 16 is a view illustrating a second example of the cut-out surface of the object for each laser processing condition.

FIG. 17 is a view illustrating the second example of the cut-out surface of the object for each laser processing condition.

FIG. 18 is a view illustrating a relationship between the trefoil aberration intensity and an oblique angle of a fracture.

FIG. 19 is a view illustrating a relationship between the trefoil aberration intensity and the oblique angle of the fracture.

FIG. 20 is a view illustrating an object to which a first example of a laser processing method is applied.

FIG. 21 is a view illustrating a first process of the first example of the laser processing method.

FIG. 22 is a view illustrating an example of a cut-out surface of an object due to leaked light damage suppressing processing.

FIG. 23 is a view illustrating an object to which a second example of the laser processing method is applied.

FIG. 24 is a view illustrating a first process of the second example of the laser processing method.

### DESCRIPTION OF EMBODIMENTS

Hereinafter, embodiments of the present disclosure will be described in detail with reference to the drawings. In the drawings, the same or corresponding portions are denoted by the same reference numerals, and redundant description may be omitted.

### Configuration of Laser Processing Apparatus

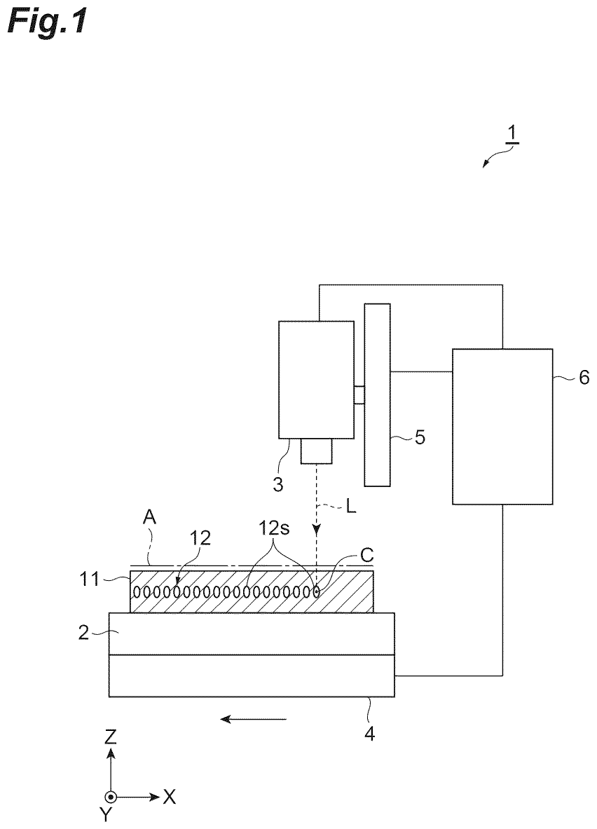

As illustrated in FIG. 1, a laser processing apparatus 1 includes a support unit 2, an irradiation unit 3, drive units 4 and 5, and a control unit 6. The laser processing apparatus 1 irradiates an object 11 with laser light L to form a modified region 12 in the object 11.

The support unit 2 supports the object 11, for example, by holding a film pasted to the object 11. In this embodiment, the support unit 2 is movable in each of an X-direction and a Y-direction, and can rotate around an axial line parallel to a Z-direction as a rotation axis. As an example, the X-direction and the Y-direction are a first horizontal direction and a second horizontal direction orthogonal to each other, and the Z-direction is a vertical direction.

The irradiation unit 3 converges the laser light L having permeability with respect to the object 11 and irradiates the object 11 with the laser light L. In this embodiment, the irradiation unit 3 is movable in the Z-direction. When the laser light L is converged into the object 11 supported to the support unit 2, the laser light L is notably absorbed in a portion corresponding to a converging spot C of the laser light L, and the modified region 12 is formed inside the object 11. Note that, the converging spot C is also referred to as a converging region or a converging point.

The modified region 12 is a region that differs from its surrounding unmodified regions in density, refractive index, mechanical strength, and other physical properties. Examples of the modified region 12 include a molten processed region, a crack region, a dielectric breakdown region, a refractive index changing region, and the like. A fracture is formed on an incident side of the laser light L and an opposite side thereof from the modified region 12. The modified region 12 and the fracture are used to cut out the object 11.

As an example, when the converging spot C can be relatively moved along a line A parallel to the X-direction set to the object 11, a plurality of modified spots 12s are formed so as to be arranged in a row along the line A. One of the modified spots 12s is formed by irradiation with one pulse of laser light L. One row of modified region 12 is a set of the plurality of modified spots 12s arranged in a row. Adjacent modified spots 12s may be connected to each other or may be separated from each other depending on a relative moving speed of the converging spot C with respect to the object 11 and a repetition frequency of the laser light L.

The drive unit 4 supports the support unit 2 and drives the support unit 2. In this embodiment, the drive unit 4 moves the support unit 2 in each of the X-direction and the Y-direction, and rotates the support unit 2 around an axial line parallel to the Z-direction as the rotation axis. The drive unit 5 supports the irradiation unit 3 and drives the irradiation unit 3. In this embodiment, the drive unit 5 moves the irradiation unit 3 in the Z-direction. As an example, in the laser processing apparatus 1, the drive unit 4 rotates the support unit 2 so that the line A becomes parallel to the X-direction, the drive unit 4 moves the support unit 2 in the Y-direction so that the converging spot C is located on the line A, the drive unit 5 moves the irradiation unit 3 in the Z-direction so that the converging spot C is located inside the object 11, and the drive unit 4 moves the support unit 2 so that the converging spot C is relatively moved along the line A.

The control unit 6 controls the support unit 2, the irradiation unit 3, and the drive units 4 and 5. The control unit 6 includes a processing unit, a storage unit, and an input receiving unit (not illustrated). The processing unit is configured as a computer device including a processor, a memory, a storage, a communication device, and the like. In the processing unit, the processor executes software (program) read into the memory or the like, and controls reading and writing of data in the memory and the storage, and communication by the communication device. The storage unit is, for example, a hard disk or the like, and stores various data. The input receiving unit is an interface unit that displays various pieces of information, and receives input of the various pieces of information from a user. The input receiving unit constitutes, for example, a graphical user interface (GUI).

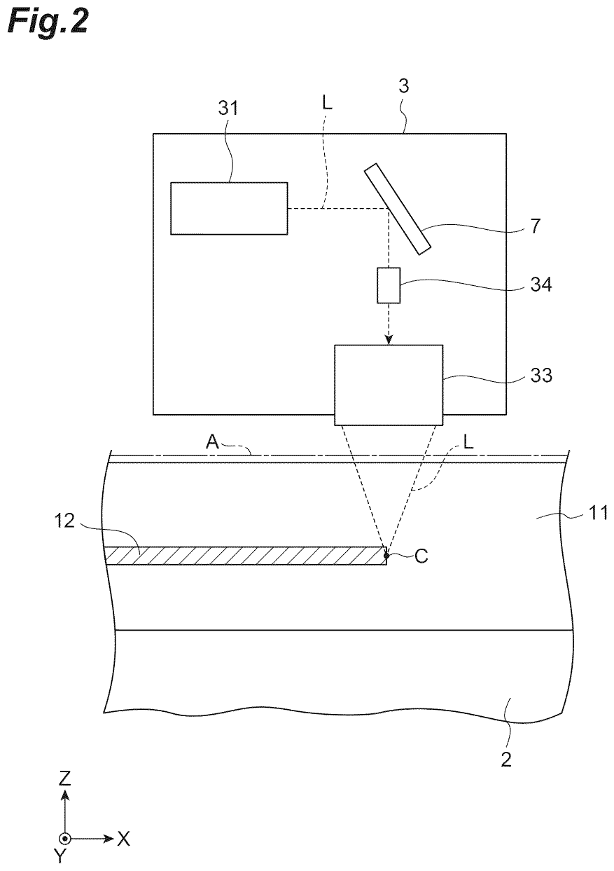

As illustrated in FIG. 2, the irradiation unit 3 includes a light source 31, a spatial light modulator 7, a converging unit 33, and a 4f lens unit 34. The light source 31 emits the laser light L, for example, by a pulse oscillation method. The spatial light modulator 7 modulates the laser light L emitted from the light source 31 by displaying a modulation pattern. The converging unit 33 is constituted by at least one lens, and converges the laser light L modulated by the spatial light modulator 7 to the object 11. The 4f lens unit 34 transfers an image of the laser light L on a modulation surface of the spatial light modulator 7 to an entrance pupil plane of the converging unit 33. In addition, the light source 31 may be provided at the outside of the irradiation unit 3, and the laser light L emitted from the light source 31 may be guided to the irradiation unit 3. In addition, the irradiation unit 3 may include another optical system. As an example, the irradiation unit 3 may include an optical system (for example, an attenuator, a beam expander, or the like) disposed on an optical path between the light source 31 and the spatial light modulator 7.

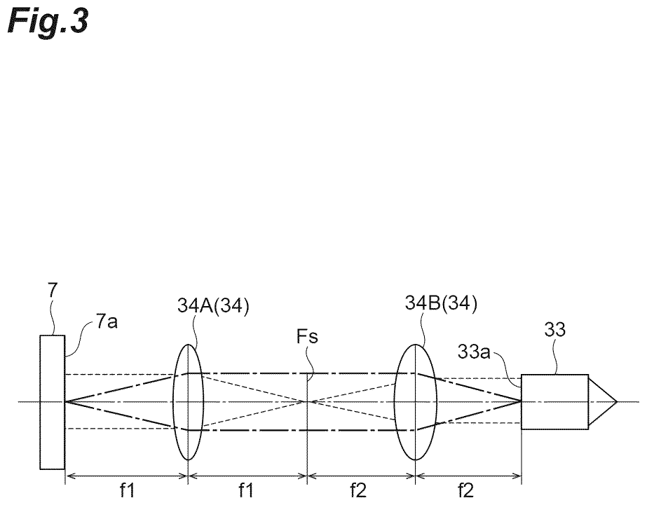

As illustrated in FIG. 3, the 4f lens unit 34 includes a pair of lenses 34A and 34B. The pair of lenses 34A and 34B is disposed on an optical path of the laser light L that travels from the spatial light modulator 7 to the converging unit 33. The pair of lenses 34A and 34B constitute a both-side telecentric optical system in which the modulation surface 7a of the spatial light modulator 7 and an entrance pupil plane (pupil plane) 33a of the converging unit 33 are in an imaging relationship. According to this, an image of the laser light L on the modulation surface 7a of the spatial light modulator 7 (an image of the laser light L modulated by the spatial light modulator 7) is transferred to (imaged on) the entrance pupil plane 33a of the converging unit 33. Note that, in FIG. 3, f1 and f2 indicate focal distances of the lenses 34A and 34B, respectively, and Fs indicates a Fourier plane.

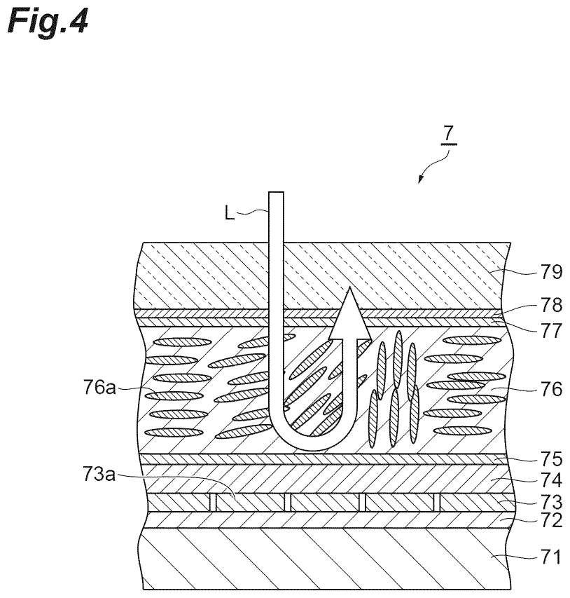

As illustrated in FIG. 4, the spatial light modulator 7 is a spatial light modulator (SLM) of reflective liquid crystal on silicon (LCOS). The spatial light modulator 7 is configured by stacking a drive circuit layer 72, a pixel electrode layer 73, a reflective film 74, an alignment film 75, a liquid crystal layer 76, an alignment film 77, a transparent conductive film 78, and a transparent substrate 79 in this order on a semiconductor substrate 71.

The semiconductor substrate 71 is, for example, a silicon substrate. The drive circuit layer 72 constitutes an active matrix circuit on the semiconductor substrate 71. The pixel electrode layer 73 includes a plurality of pixel electrodes 73a arranged in a matrix along a surface of the semiconductor substrate 71. Each of the pixel electrodes 73a is formed from, for example, a metal material such as aluminum. A voltage is applied to each of the pixel electrodes 73a by the drive circuit layer 72.

The reflective film 74 is, for example, a dielectric multilayer film. The alignment film 75 is provided on a surface of the liquid crystal layer 76 on the reflective film 74 side, and the alignment film 77 is provided on a surface of the liquid crystal layer 76 on a side opposite to the reflective film 74. Each of the alignment films 75 and 77 is formed from, for example, a polymer material such as polyimide, and a contact surface of each of the alignment films 75 and 77 with the liquid crystal layer 76 is subjected to, for example, a rubbing treatment. The alignment films 75 and 77 cause liquid crystal molecules 76a included in the liquid crystal layer 76 to be arranged in a certain direction.

The transparent conductive film 78 is provided on a surface of the transparent substrate 79 on the alignment film 77 side, and faces the pixel electrode layer 73 with the liquid crystal layer 76 and the like interposed therebetween. The transparent substrate 79 is, for example, a glass substrate. The transparent conductive film 78 is formed from, for example, a light transmissive and conductive material such as ITO. The transparent substrate 79 and the transparent conductive film 78 allow the laser light L to pass therethrough.

In the spatial light modulator 7 configured as described above, when a signal indicating a modulation pattern is input from the control unit 6 to the drive circuit layer 72, a voltage corresponding to the signal is applied to each of pixel electrodes 73a, and an electric field is formed between each of the pixel electrodes 73a and the transparent conductive film 78. When the electric field is formed, in the liquid crystal layer 76, the arrangement direction of the liquid crystal molecules 76a varies in each region corresponding to each of the pixel electrodes 73a, and the refractive index varies in each region corresponding to each of the pixel electrodes 73a. This state is a state in which the spatial light modulator 7 displays the modulation pattern.

In a state in which the spatial light modulator 7 displays the modulation pattern, when the laser light L is incident to the liquid crystal layer 76 from the outside through the transparent substrate 79 and the transparent conductive film 78, is reflected by the reflective film 74, and is emitted from the liquid crystal layer 76 to the outside through the transparent conductive film 78 and the transparent substrate 79, an intensity, an amplitude, a phase, polarization, and the like of the laser light L are modulated in correspondence with a modulation pattern displayed on the liquid crystal layer 76. Note that, the modulation surface 7a shown in FIG. 3 corresponds to the liquid crystal layer 76.

### Laser Processing Method Using Trefoil Aberration Pattern

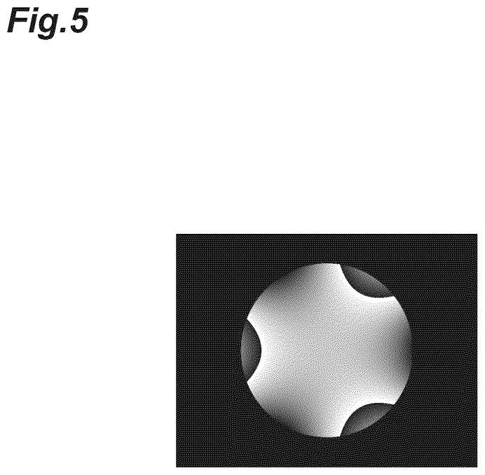

In the laser processing apparatus 1, the control unit 6 can cause the spatial light modulator 7 to display the modulation pattern including a trefoil aberration pattern. FIG. 5 is a view illustrating an example of the trefoil aberration pattern. The trefoil aberration is one of Zernike's third-order aberration. Note that, the spherical aberration and astigmatism are included in Zernike's second-order aberrations, and coma aberration and trefoil aberration are included in the Zernike's third-order aberrations.

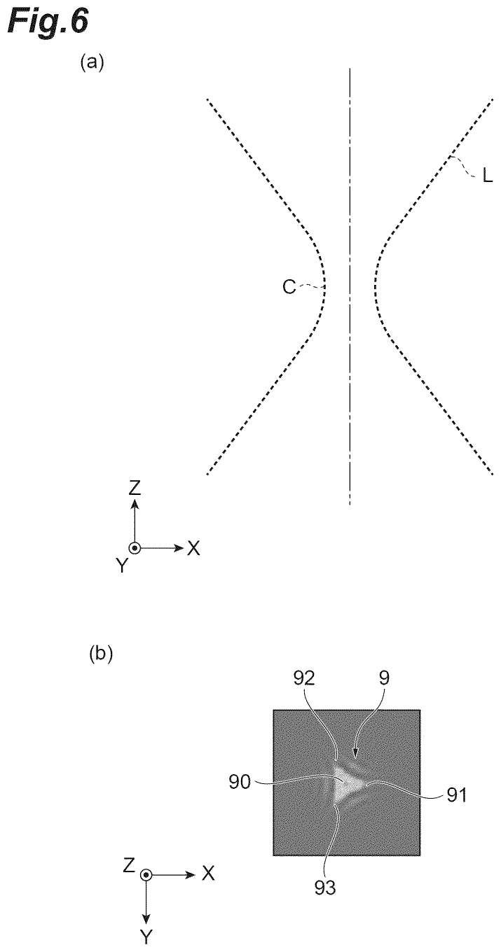

When the laser light L modulated by the spatial light modulator 7 displaying the trefoil aberration pattern is converged by the converging unit 33, as illustrated in (a) in FIG. 6, the laser light L is most narrowed at a converging spot C. At this time, a beam shape 9 of the laser light L at the converging spot C (that is, an intensity distribution of the laser light L within “a plane that is orthogonal to an optical axis (one-dotted line shown in (a) in FIG. 6) of the laser light L and includes the converging spot C”) becomes a beam shape that includes a central portion 90, and a first extension portion 91, a second extension portion 92, and a third extension portion 93 extending radially from a central portion 90, and has the highest intensity at the central portion 90, as illustrated in (b) in FIG. 6. As an example, the width of each of the first extension portion 91, the second extension portion 92, and the third extension portion 93 decreases as being away from the central portion 90, and the intensity of each of the first extension portion 91, the second extension portion 92, and the third extension portion 93 decreases as being away from the central portion 90. As an example, the beam shape 9 of the laser light L is a shape in which each side of a triangle is curved inward.

Note that, the modulation pattern including the trefoil aberration pattern includes not only a modulation pattern including only the trefoil aberration pattern, but also a modulation pattern including the trefoil aberration pattern and other patterns. Even in a case where the modulation pattern includes a pattern other than the trefoil aberration pattern, when the laser light L modulated by the spatial light modulator 7 displaying the modulation pattern including the trefoil aberration pattern is converged by the converging unit 33, the beam shape 9 of the laser light L at the converging spot C includes the central portion 90, and the first extension portion 91, the second extension portion 92, and the third extension portion 93 extending radially from the central portion 90, and has the highest intensity at the central portion 90. As an example, when the laser light L modulated by the spatial light modulator 7 displaying a modulation pattern including the trefoil aberration pattern and the astigmatism pattern is converged by the converging unit 33, a plurality of converging spots C may appear. Even in such a case, the beam shape 9 of the laser light L at each of the converging spots C (in this case, the intensity distribution of the laser light L within a “plane that is orthogonal to the optical axis of the laser light L converged at the converging spot C and includes the converging spot C”) has a beam shape that includes the central portion 90 and the first extension portion 91, the second extension portion 92, and the third extension portion 93 extending radially from the central portion 90, and has the highest intensity at the central portion 90.

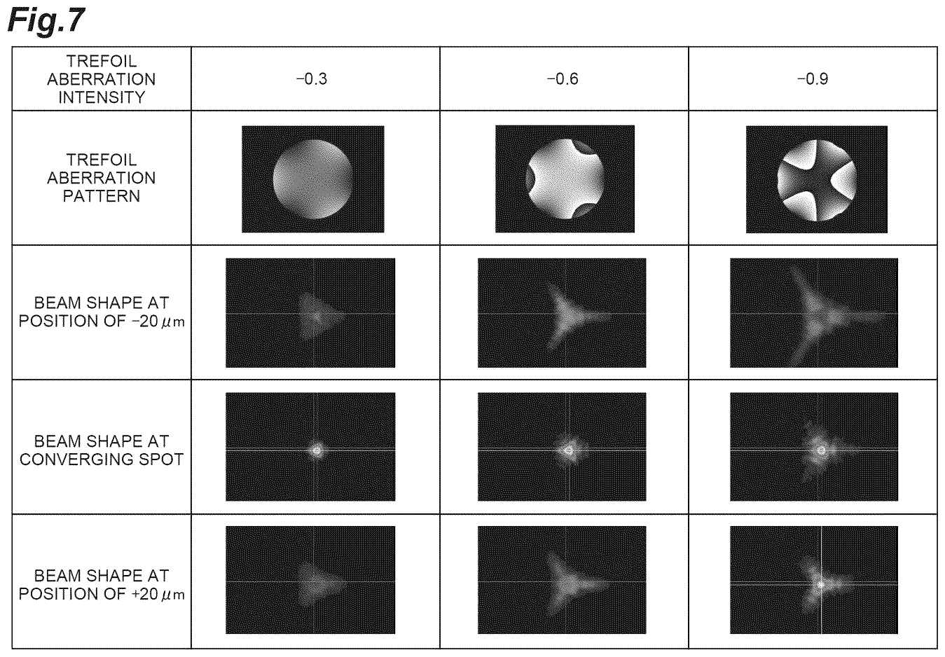

FIG. 7 is a view illustrating an example of the beam shape of the laser light L for each trefoil aberration intensity. An absolute value of the trefoil aberration intensity represents the strength of the trefoil aberration, and the larger the absolute value of the trefoil aberration intensity is, the stronger the trefoil aberration is (accordingly, “strong trefoil aberration intensity” represents that the absolute value of the trefoil aberration intensity is large). A positive or negative sign of the trefoil aberration intensity represents a direction of the trefoil aberration, and the direction of the trefoil aberration with the positive sign differs by 180 degrees from that of the trefoil aberration with the negative sign. FIG. 7 shows a camera image captured by a camera as the beam shape of the laser light L.

As shown in FIG. 7, when the laser light L is modulated by the trefoil aberration pattern having any of the trefoil aberration intensities, the beam shape 9 of the laser light L at the converging spot C becomes a beam shape that includes the central portion 90, the first extension portion 91, the second extension portion 92, and the third extension portion 93, and has the highest intensity at the central portion 90 (refer to (b) in FIG. 6). At this time, a beam shape of the laser light L at a position of −20 μm and the beam shape of the laser light L at a position of +20 μm also become a beam shape having a similar shape and a similar direction as in the beam shape 9 of the laser light L at the converging spot C. When taking a look at the camera image, the beam shape 9 of the laser light L at the converging spot C may appear to be directed in the opposite direction to the beam shape of the laser light L at the position of −20 μm and the beam shape of the laser light L at the position of +20 μm, but even in such a case, it can be seen that the beam shape is directed to the same side as in the beam shapes when not only a high-intensity portion but also a low-intensity portion is included. The “−20 μm position” is a position spaced apart from the converging spot C to the converging unit 33 side by 20 μm, and the “+20 μm position” is a position that is spaced apart from the converging spot C to a side opposite to the converging unit 33 by 20 μm.

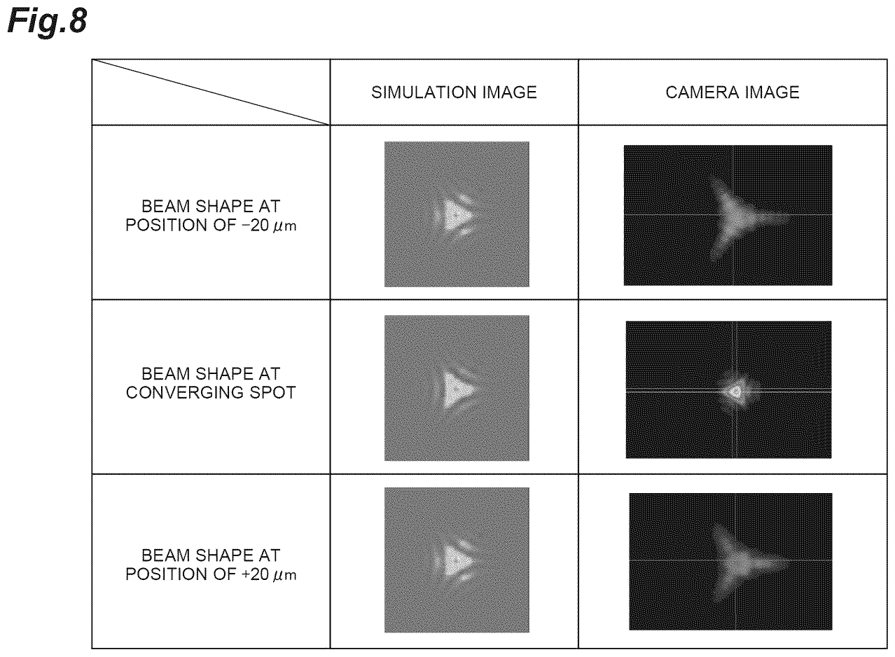

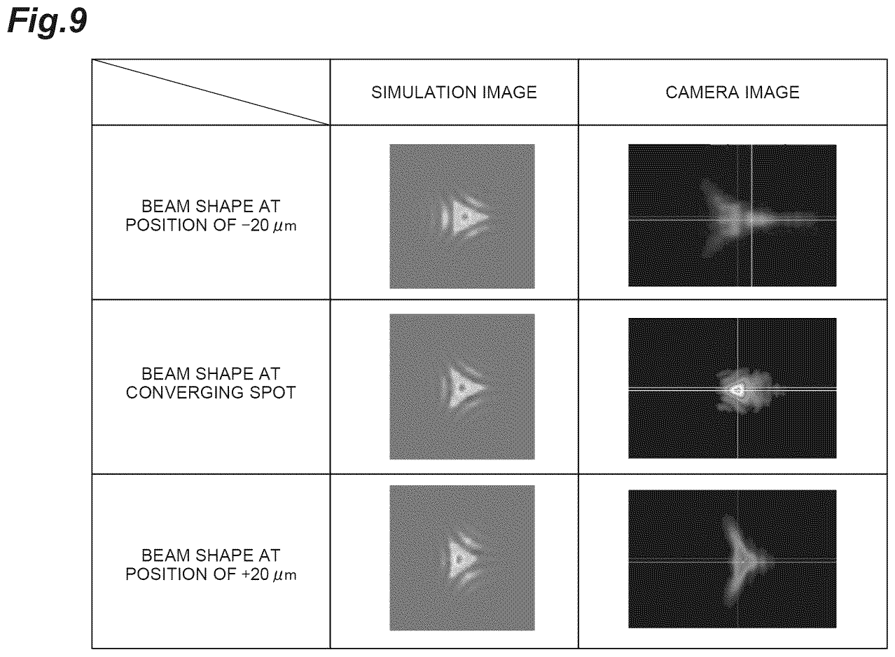

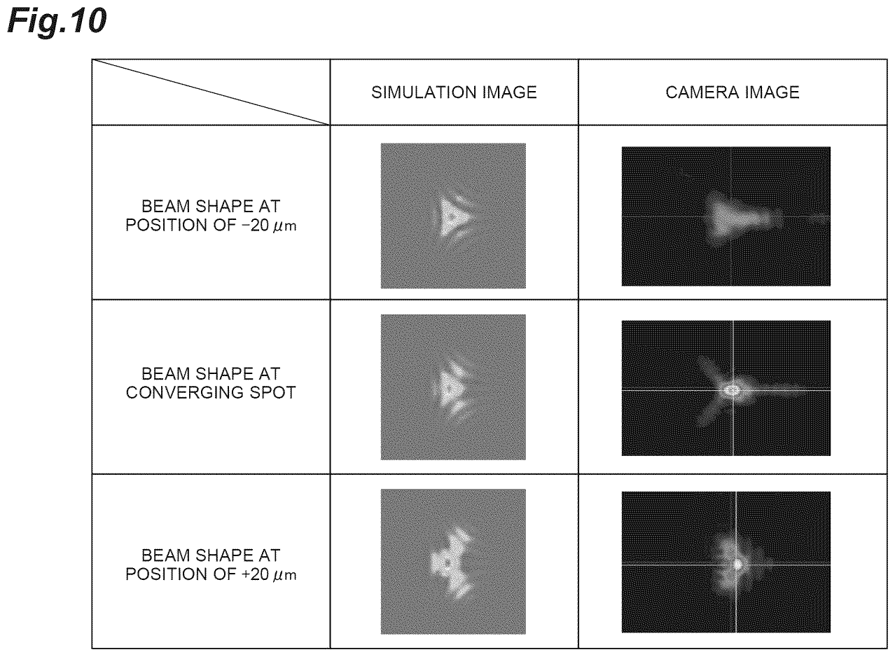

FIG. 8 is a view illustrating an example of the beam shape of the laser light L modulated by the trefoil aberration pattern. FIG. 9 is a view illustrating an example of a beam shape of the laser light L modulated by the trefoil aberration pattern and the astigmatism pattern (that is, a modulation pattern in which the patterns are superimposed on each other). FIG. 10 is a view illustrating an example of a beam shape of the laser light L modulated by the trefoil aberration pattern, the astigmatism pattern, and the spherical aberration pattern (that is, a modulation pattern in which the patterns are superimposed on each other). FIG. 8, FIG. 9, and FIG. 10 show a simulation image obtained by simulation and a camera image captured by a camera as the beam shape of the laser light L. In each of FIG. 8, FIG. 9, and FIG. 10, the trefoil aberration intensity of the trefoil aberration pattern is −0.6.

As illustrated in FIG. 8, FIG. 9, and FIG. 10, When the laser light L is modulated by a modulation pattern including the trefoil aberration pattern, the beam shape 9 of the laser light L in the converging spot C becomes a beam shape including the central portion 90, the first extension portion 91, the second extension portion 92, and the third extension portion 93, and having the highest intensity at the central portion 90 (refer to (b) in FIG. 6). At this time, the beam shape of the laser light L at a position of−20 μm and the beam shape of the laser light L at a position of +20 μm also become beam shapes having a similar shape and a similar direction as in the beam shape 9 of the laser light L at the converging spot C. When taking a look at the camera image, the beam shape 9 of the laser light L at the converging spot C may appear to be directed in the opposite direction to the beam shape of the laser light L at the position of −20 μm and the beam shape of the laser light L at the position of +20 μm, but even in such a case, it can be seen that the beam shape is directed to the same side as in the beam shapes when not only a high-intensity portion but also a low-intensity portion is included.

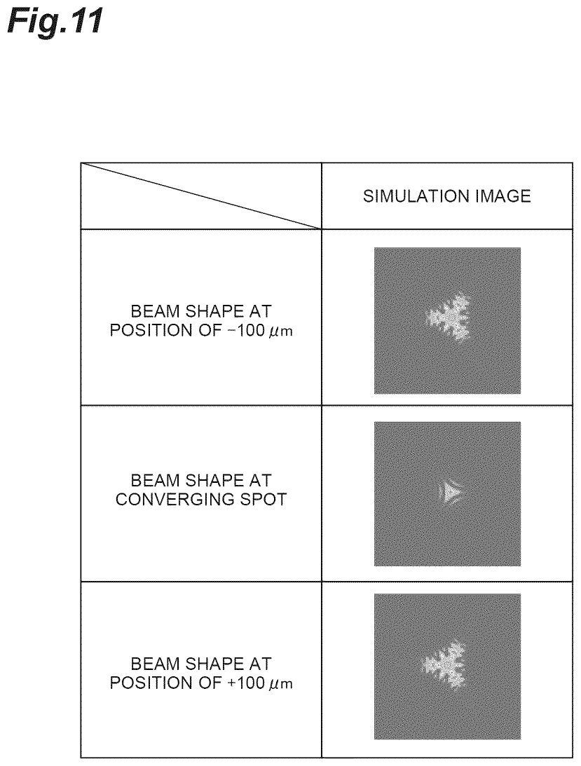

FIG. 11 is a view illustrating an example of the beam shape of the laser light L modulated by the trefoil aberration pattern. In this case, the trefoil aberration intensity of the trefoil aberration pattern is −0.5. As shown in FIG. 11, the beam shape of the laser light L at a position of −100 um and the beam shape of the laser light L at a position of +100 μm becomes beam shapes directed to the opposite side to the beam shape 9 of the laser light L at the converging spot C. Note that, the “−100 μm position” is a position spaced apart from the converging spot C to the converging unit 33 side by 100 μm, and the “+100 μm position” is a position that is spaced apart from the converging spot C to a side opposite to the converging unit 33 by 100 μm.

In contrast, as described above, the beam shape of the laser light L at the position of −20 μm and the beam shape of the laser light L at the position of +20 μm become beam shapes having a similar shape and a similar direction as in the beam shape 9 of the laser light L at the converging spot C (refer to FIG. 7, FIG. 8, FIG. 9, and FIG. 10). Particularly, the beam shape of the laser light L at the position of−20 μm more clearly shows the beam shape 9 of the laser light L at the converging spot C as compared with the beam shape of the laser light L at the position of +20 μm. Accordingly, in a case where the laser light L modulated by the modulation pattern including the trefoil aberration pattern is converged, in order to estimate the beam shape 9 of the laser light L at the converging spot C, the beam shape of the laser light L at the position of −20 μm may be captured by a camera and the camera image may be observed.

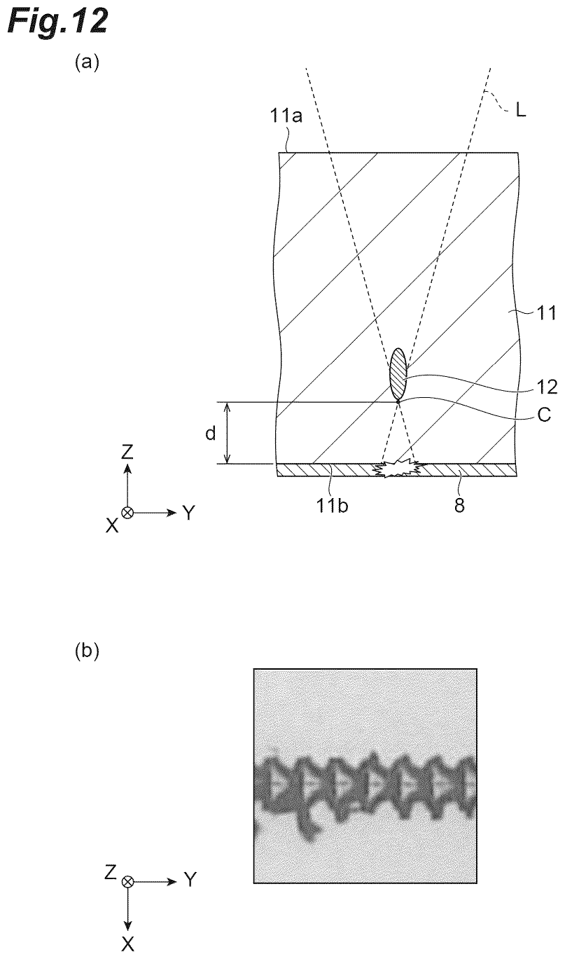

In addition, as illustrated in (a) in FIG. 12, when a metal film 8 is formed on a second surface 11b of the object 11 that is a silicon wafer, a first surface 11a of the object 11 is set as an incident surface of the laser light L, the converging spot C is aligned with a position inside the object 11 which is spaced apart from the second surface 11b by 20 to 30 μm, and the object 11 is irradiated with the laser light L, in a case where the laser light L modulated by the modulation pattern including the trefoil aberration pattern is converged, a damage having a similar shape and a similar direction as in the beam shape 9 of the laser light L at the converging spot C is formed on the metal film 8 as shown in (b) in FIG. 12. Accordingly, in a case where the laser light L modulated by the modulation pattern including the trefoil aberration pattern is converged, in order to estimate the beam shape 9 of the laser light L at the converging spot C, a damage may be formed on the metal film 8 as described above and the damage may be observed.

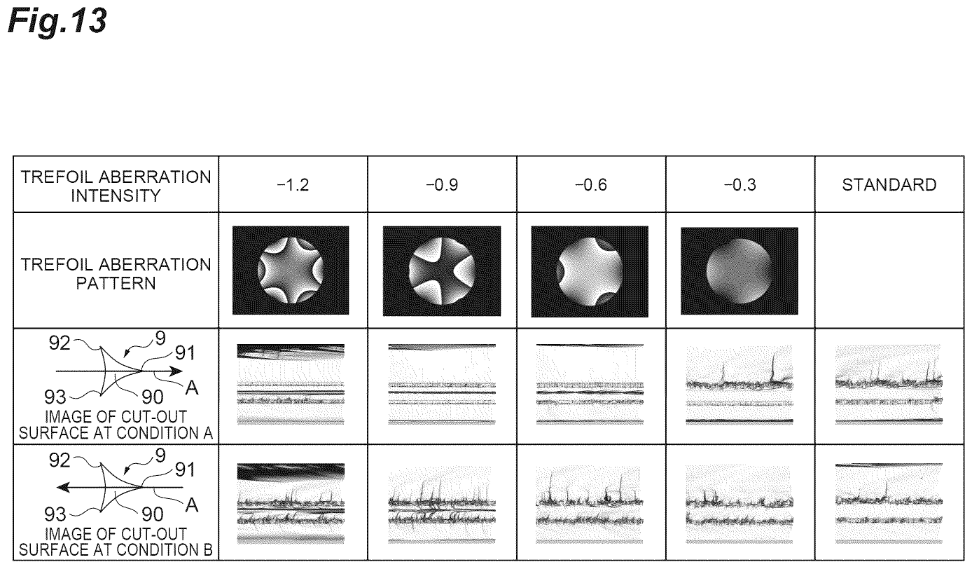

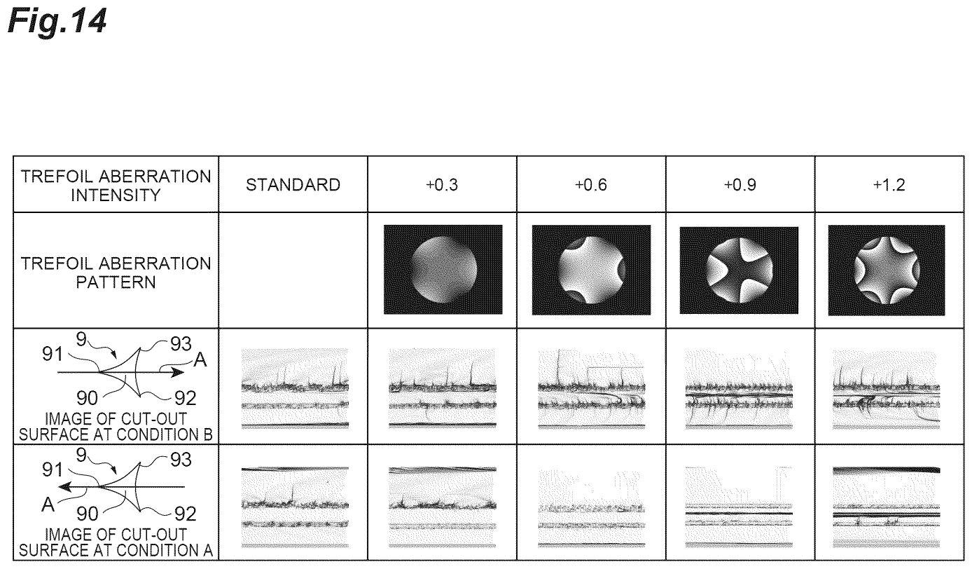

Based on the above description, a first example of a modified region and a fracture (a fracture extending from a modified region when forming the modified region) formed by a laser processing method using the trefoil aberration pattern will be described. FIG. 13 and FIG. 14 are views illustrating a first example of a cut-out surface of the object 11 for each laser processing condition. FIG. 13 and FIG. 14 show a cut-out surface of the object 11 in a case where “two rows of modified regions aligned in a thickness direction of a silicon wafer are formed along a line A inside the object 11 that is a silicon wafer, and then the object 11 is cut out along the line A by expanding”.

In FIG. 13 and FIG. 14, “Condition A” is a laser processing condition in which the converging spot C is moved relatively in “a direction indicated by an arrow on a line A” (rightward in FIG. 13 and leftward in FIG. 14), and at that time, the beam shape 9 of the laser light L at the converging spot C enters (1) “a state in which the central portion 90 and the first extension portion 91 are located on the line A, the second extension portion 92 is located on a first side (an upper side in FIG. 13 and a lower side in FIG. 14) with respect to the line A, and the third extension portion 93 is located on a second side (a lower side in FIG. 13 and an upper side in FIG. 14) with respect to the line A”, and (2) “a state in which the first extension portion 91 is located on a front side of a direction in which the converging spot C is moved relatively along the line A, and the second extension portion 92 and the third extension portion 93 are located on a rear side of the direction”.

In addition, “Condition B” is a laser processing condition in which the converging spot C is moved relatively in “the direction indicated by the arrow on line A” (leftward in FIG. 13 and rightward in FIG. 14), and at that time, the beam shape 9 of the laser light L at the converging spot C enters (1) “a state in which the central portion 90 and the first extension portion 91 are located on the line A, the second extension portion 92 is located on the second side (an upper side in FIG. 13 and a lower side in FIG. 14) with respect to the line A, and the third extension portion 93 is located on the first side (a lower side in FIG. 13 and an upper side in FIG. 14) with respect to the line A”, and (3) “a state in which the first extension portion 91 is located on a rear side of the direction in which the converging spot C is moved relatively along the line A, and the second extension portion 92 and the third extension portion 93 are located on a front side of the direction”.

Note that, “Standard” in a column of “Condition A” is a laser processing condition that is different from “Condition A” only in that the modulation pattern does not include the trefoil aberration pattern. In addition, “Standard” in a column of “Condition B” is a laser processing condition that is different from “Condition B” only in that the modulation pattern does not include the trefoil aberration pattern.

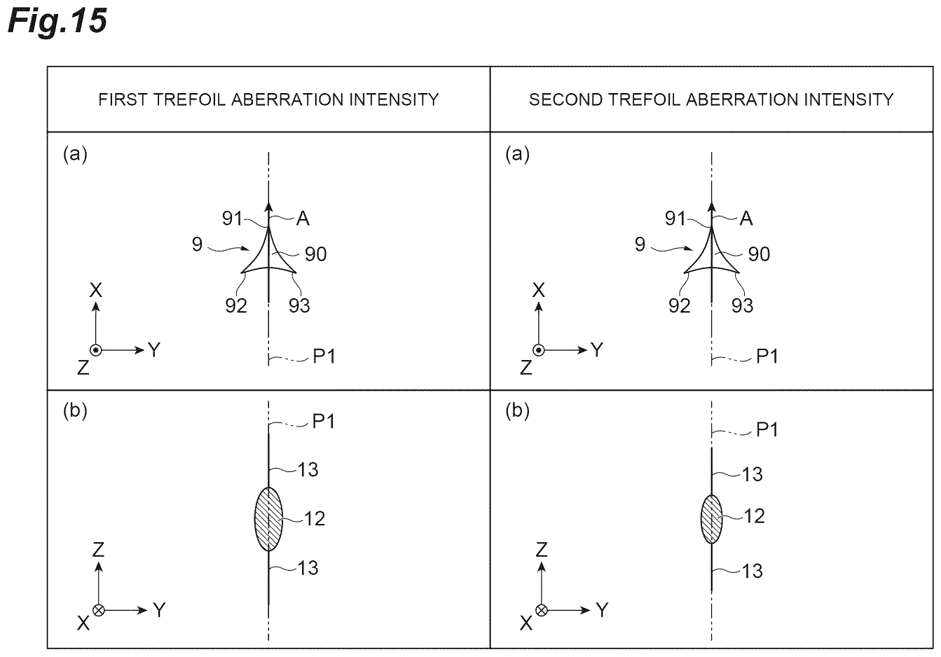

Description will be given of findings obtained from the state of the cut-out surface of the object 11 as shown in FIG. 13 and FIG. 14 with reference to FIG. 15.

First, as shown in FIG. 15, in a case where the modified region 12 is formed in the object 11 along the line A, and a fracture 13 is formed in the object 11 from the modified region 12 along a first plane P1 parallel to both the incident direction of the laser light L (Z-direction) and the extension direction of the line A (X-direction), when reducing the width of the fracture 13 in the incident direction of the laser light L, the spatial light modulator 7 may be caused to display a modulation pattern including the trefoil aberration pattern so that the first extension portion 91 is located on the line A, the second extension portion 92 is located on one side of the line A, and the third extension portion 93 is located on the other side of the line A (“Condition A” and “Condition B” in FIG. 13 and FIG. 14).

Note that, a reduction in the width of the fracture in the incident direction of the laser light L on the cut-out surface of the object 11 as shown in FIG. 13 and FIG. 14 can be seen from the fact that a black strip extending in a left-right direction is formed between the two rows of modified regions (black strip regions extending in the left-right direction). The reason for this is as follows. In a case where the object 11 is cut out by expanding in a state in which the fracture extending from each modified region during formation of the two rows of modified regions is not connected between the two rows of modified regions, the black strip extending in the left-right direction may be formed.

In addition, as shown in FIG. 15, when forming a modified region 12 in the object 11 along the line A and forming a fracture 13 in the object 11 along the first plane P1, in order to reduce not only the width of the fracture 13 in the incident direction of the laser light L but also the width of the modified region 12 in the incident direction of the laser light L and to prevent the fracture 13 from meandering with respect to the line A, the spatial light modulator 7 may be caused to display a modulation pattern including the trefoil aberration pattern so that the first extension portion 91 is located on a front side of a direction in which the converging spot C is moved relatively along the line A and the second extension portion 92 and the third extension portion 93 are located on a rear side of the direction (“Condition A” in FIG. 13 and FIG. 14). Note that, suppression of the meandering of the fracture 13 with respect to the line A on the cut-out surface of the object 11 as shown in FIG. 13 and FIG. 14 can be seen from the fact that a black strip (called twist hackle) extending vertically from two rows of modified regions are further reduced in “Condition A” as compared with “Standard” and “Condition B”.

Note that, in a case where the converging spot C is moved relatively along each of a first line and a second line set to the object 11 as the line A, when the direction in which the converging spot C is moved relatively along the first line is different from the direction in which the converging spot C is moved relatively along the second line, a direction of a modulation pattern including the trefoil aberration pattern in the spatial light modulator 7 may be switched so that the first extension portion 91 is located on a front side of the direction in which the converging spot C is moved relatively along each of the first line and the second line, and the second extension portion 92 and the third extension portion 93 are located on a rear side of the direction.

In addition, as shown in FIG. 15, when the width of at least one of the modified region 12 and the fracture 13 in the incident direction of the laser light L (Z-direction) is set to a first width, the spatial light modulator 7 may be caused to display a modulation pattern including the trefoil aberration pattern with a first trefoil aberration intensity, and when the width of at least one of the modified region 12 and the fracture 13 is set to a second width smaller than the first width, the spatial light modulator 7 may be caused to display a modulation pattern including the trefoil aberration pattern with a second trefoil aberration intensity stronger than the first trefoil aberration intensity. In the example shown in FIG. 15, the widths of the modified region 12 and the fracture 13 in the incident direction of the laser light L are smaller at the second trefoil aberration intensity as compared with the first trefoil aberration intensity.

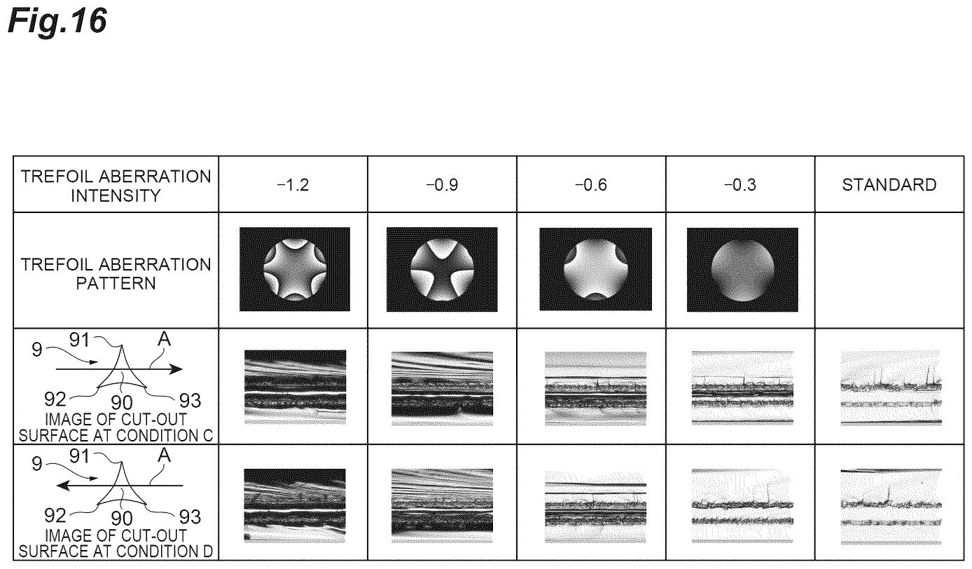

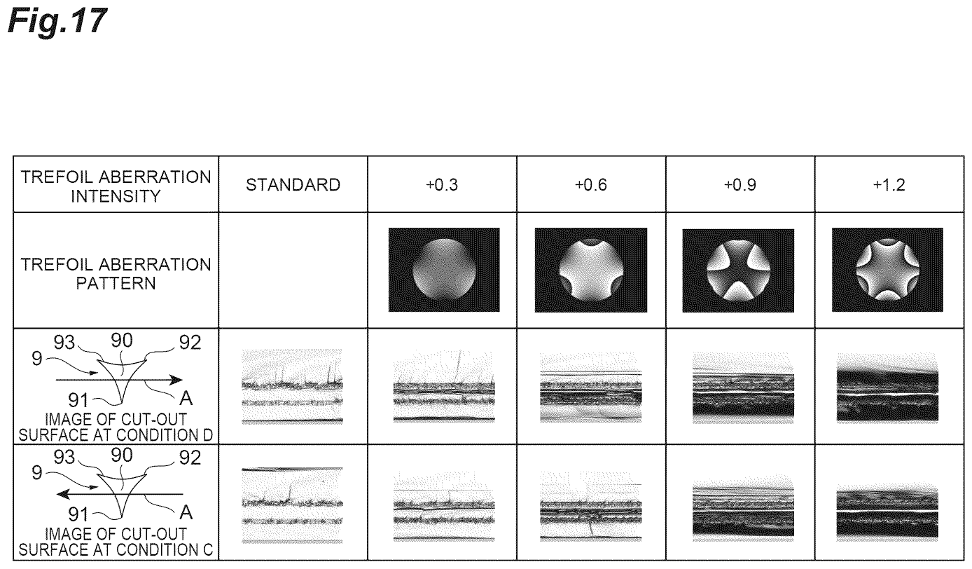

Next, a second example of the modified region and the fracture (fracture extending from the modified region when forming the modified region) formed by the laser processing method using the trefoil aberration pattern will be described. FIG. 16 and FIG. 17 are views illustrating a second example of the cut-out surface of the object 11 for each laser processing condition. FIG. 16 and FIG. 17 show the cut-out surface of the object 11 in a case where “two rows of modified regions aligned in a thickness direction of a silicon wafer are formed along the line A inside the object 11 that is the silicon wafer, and then the object 11 is cut out along the line A by expanding”.

In FIG. 16 and FIG. 17, “Condition C” is a laser processing condition in which the converging spot C is moved relatively in “the direction indicated by the arrow on the line A” (rightward in FIG. 16 and leftward in FIG. 17), and at that time, the beam shape 9 of the laser light L at the converging spot C enters (4) “a state in which the central portion 90 is located on the line A, the first extension portion 91 is located on a first side (an upper side in FIG. 16, and a lower side in FIG. 17) with respect to the line A, and the second extension portion 92 and the third extension portion 93 are located on a second side (a lower side in FIG. 16, and an upper side in FIG. 17) with respect to the line A”.

In addition, “Condition D” is a laser processing condition in which the converging spot C is moved relatively in “the direction indicated by the arrow on the line A” (leftward in FIG. 16 and rightward in FIG. 17), and at that time, the beam shape 9 of the laser light L at the converging spot C enters (5) “a state in which the central portion 90 is located on the line A, the first extension portion 91 is located on a second side (an upper side in FIG. 16 and a lower side in FIG. 17) with respect to the line A, and the second extension portion 92 and the third extension portion 93 are located on a first side (a lower side in FIG. 16 and an upper side in FIG. 17) with respect to the line A”.

Note that, “Standard” in a column of “Condition C” is a laser processing condition that is different from “Condition C” only in that the modulation pattern does not include the trefoil aberration pattern. In addition, “Standard” in a column of “Condition D” is a laser processing condition that is different from “Condition D” only in that the modulation pattern does not include the trefoil aberration pattern.

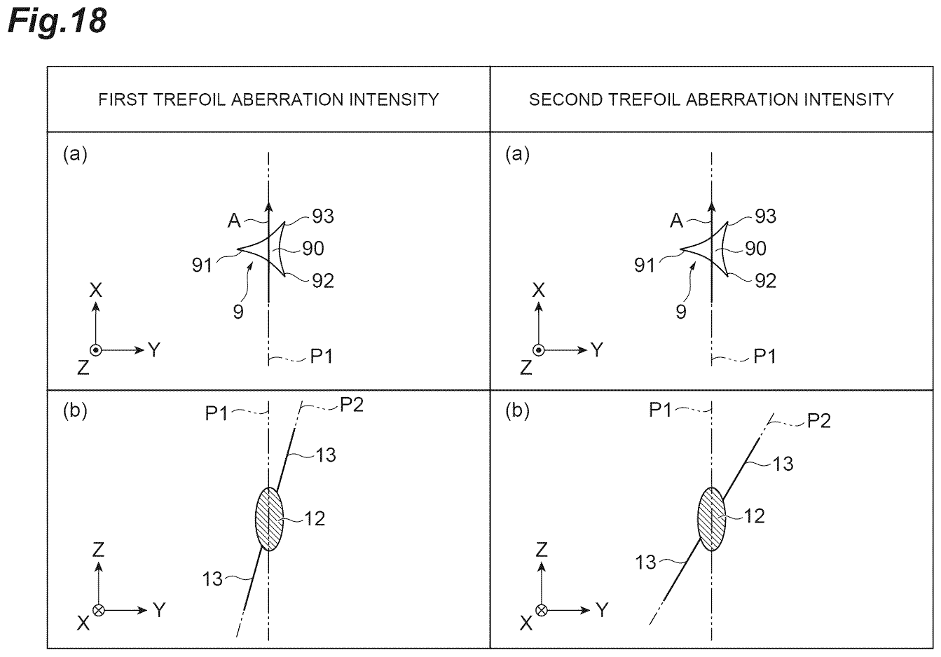

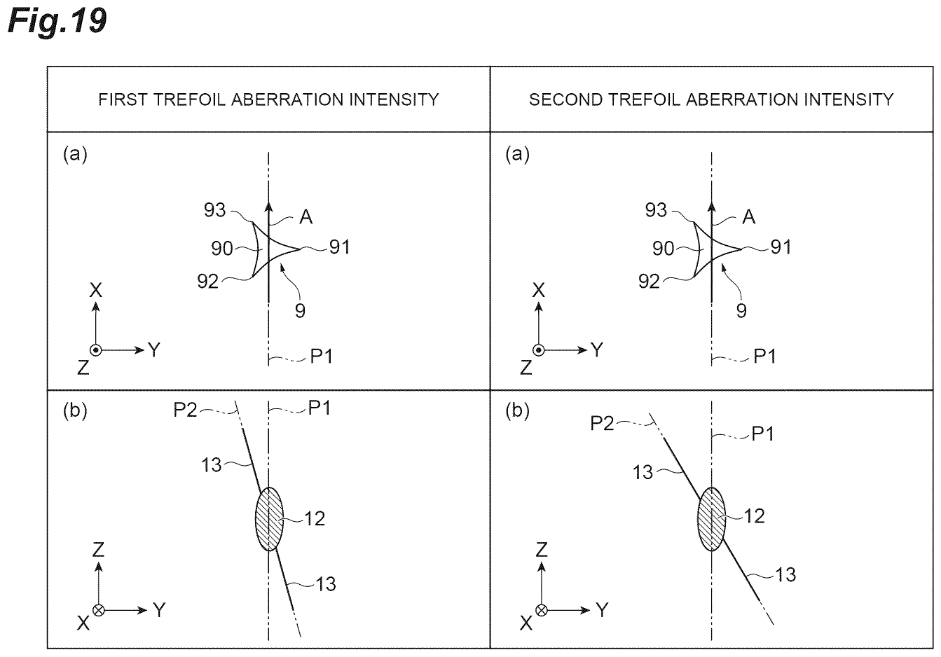

Description will be given of findings obtained from the state of the cut-out surface of the object 11 as shown in FIG. 16 and FIG. 17 with reference to FIG. 18 and FIG. 19.

First, as shown in FIG. 18, in a case where the modified region 12 is formed in the object 11 along the line A, and the fracture 13 is formed in the object 11 from the modified region 12 along a second plane P2 oblique to the first plane P1 parallel to both the incident direction of the laser light L (Z-direction) and the extension direction of the line A (X-direction), when the second plane P2 is oblique so that a region on a side opposite to the incident side of the laser light L is located on one side (left side in FIG. 18) in a direction (Y-direction) orthogonal to the first plane P1, the spatial light modulator 7 may be caused to display the modulation pattern including the trefoil aberration pattern so that the first extension portion 91 is located on one side (left side in FIG. 18) with respect to the line A, and the second extension portion 92 and the third extension portion 93 are located on the other side (right side in FIG. 18) with respect to the line A.

In addition, as illustrated in FIG. 19, in a case where the modified region 12 is formed in the object 11 along the line A and the fracture 13 is formed in the object 11 from the modified region 12 along the second plane P2 oblique to the first plane P1 parallel to both the incident direction of the laser light L (Z-direction) and the extension direction of the line A (X-direction), when the second plane P2 is oblique so that a region on a side opposite to the incident side of the laser light L is located on the other side (right side in FIG. 19) in the direction orthogonal to the first plane P1 (Y-direction), the spatial light modulator 7 may be caused to display the modulation pattern including the trefoil aberration pattern so that the first extension portion 91 is located on the other side (right side in FIG. 19) with respect to the line A and the second extension portion 92 and the third extension portion 93 are located on one side (left side in FIG. 19) with respect to the line A.

Note that, in a case of relatively moving the converging spot C along each of the first line and the second line set to the object 11 as the line A, when the direction in which the converging spot C is moved relatively along the first line is different from the direction in which the converging spot C is moved relatively along the second line, a direction of the modulation pattern including the trefoil aberration pattern in the spatial light modulator 7 may be switched so that the first extension portion 91 is located on one side with respect to each of the first line and the second line, and the second extension portion 92 and the third extension portion 93 are located on the other side with respect to each of the first line and the second line.

In addition, as illustrated in FIG. 18 and FIG. 19, the spatial light modulator 7 may be caused to display the modulation pattern including the trefoil aberration pattern with a first trefoil aberration intensity in a case where an angle between the first plane P1 and the second plane P2 (that is, an acute angle formed by the first plane P1 and the second plane P2) is set to a first angle, and the spatial light modulator 7 may be caused to display the modulation pattern including the trefoil aberration pattern with a second trefoil aberration intensity stronger than the first trefoil aberration intensity in a case where the angle is set to a second angle larger than the first angle. In addition, in the cut-out surface of the object 11 shown in FIG. 16 and FIG. 17, the stronger the trefoil aberration intensity is, the larger the angle at which the fracture is oblique. This can be seen from the fact that a black area increases as the trefoil aberration intensity increases. The cut-out surface of the object 11 shown in FIG. 16 and FIG. 17 is oblique so that a side where the black area increases is located on the front side of the paper.

### First Example of Laser Processing Method

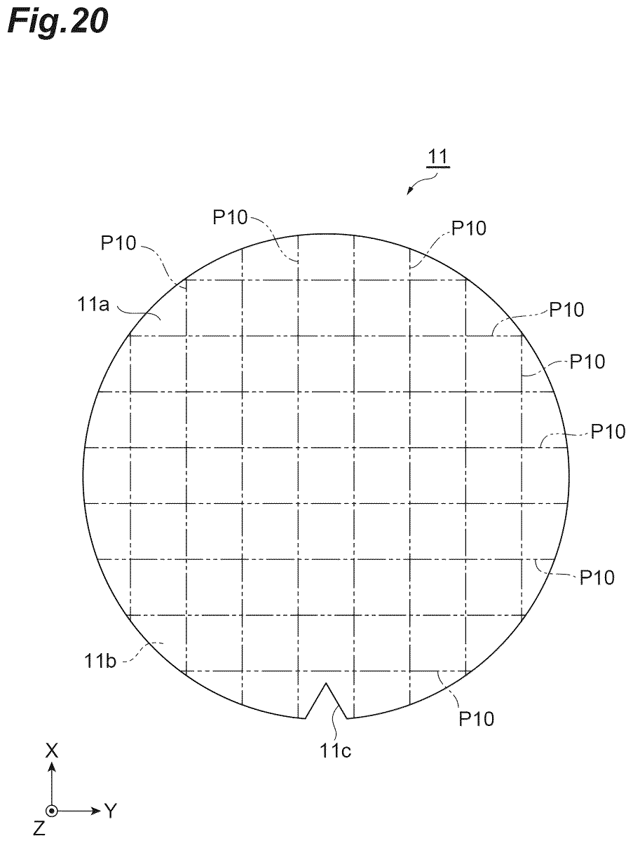

FIG. 20 is a view illustrating the object 11 to which a first example of a laser processing method is applied. As illustrated in FIG. 20, the object 11 is a semiconductor wafer having the first surface 11a and the second surface 11b. As an example, the object 11 includes a silicon wafer and a plurality of functional elements (not illustrated) formed on the first surface 11a side of the silicon wafer. The plurality of functional elements are arranged in a matrix shape along the first surface 11a with a notch 11c formed in the object 11 set as a reference. Examples of the functional elements include a light-receiving element such as a photodiode, a light-emitting element such as a laser diode, a circuit element such as a memory, and the like. The functional elements may be three-dimensionally configured by stacking a plurality of layers. Note that, an orientation flat may be formed in the object 11 instead of the notch 11c.

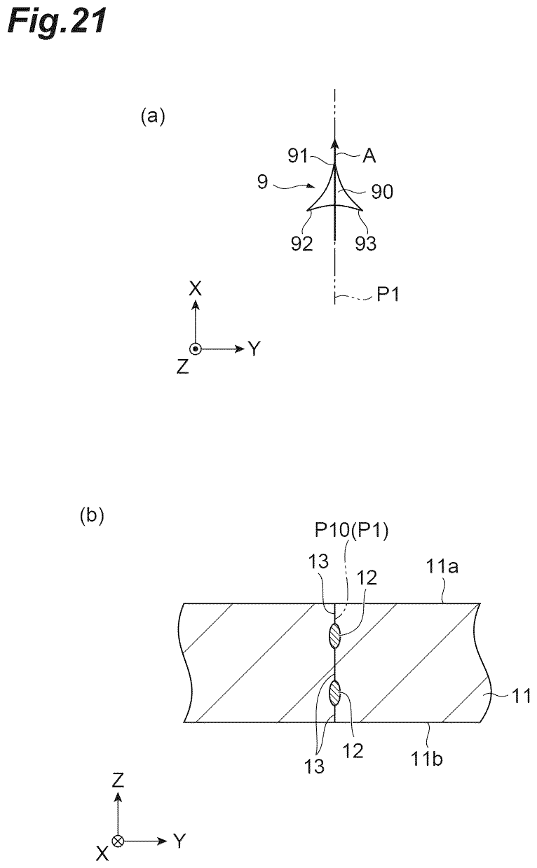

The first example of the laser processing method is carried out by the above-described laser processing apparatus 1. In the first example of the laser processing method, the object 11 shown in FIG. 20 is cut into functional elements along each of a plurality of processing planes P10 extending in a lattice shape. Each of the processing planes P10 is a plane orthogonal to the first surface 11a and the second surface 11b. In the first example of the laser processing method, as illustrated in (a) and (b) in FIG. 21, in a state in which the processing plane P10 is aligned with the first plane P1 parallel to both the incident direction of the laser light L (Z-direction) and the extension direction of the line A (X-direction), two rows of modified regions 12 aligned in the thickness direction of the object 11 are formed along the line A inside the object 11.

In the first example of the laser processing method, it is desired to form the modified region 12 in the object 11 along the line A extending within the processing plane P10, and to form the fracture 13 in the object 11 along the first plane P1. In addition, in the first example of the laser processing method, since the object 11 is thin, it is desired to reduce the widths of the modified region 12 and the fracture 13 in the incident direction of the laser light L, and to prevent the fracture 13 from meandering with respect to the line A.

Therefore, in the first example of the laser processing method, the control unit 6 causes the spatial light modulator 7 to display the modulation pattern including the trefoil aberration pattern so that the first extension portion 91 is located on the line A, the second extension portion 92 is located on one side with respect to the line A, the third extension portion 93 is located on the other side with respect to the line A, the first extension portion 91 is located on a front side of the direction in which the converging spot C is moved relatively along the line A, and the second extension portion 92 and the third extension portion 93 are located on a rear side of the direction. At this time, in a case where it is desired to reduce the widths of the modified region 12 and the fracture 13 in the incident direction of the laser light L, the control unit 6 causes the spatial light modulator 7 to display the modulation pattern including the trefoil aberration pattern with a stronger trefoil aberration intensity. Next, in a state in which the spatial light modulator 7 is caused to display the modulation pattern including the trefoil aberration pattern, the control unit 6 causes the drive unit 4 to drive the support unit 2 so that the converging spot C is moved relatively along the line A. After the above-described processes have been performed on all of the processing planes P10, the object 11 illustrated in FIG. 20 is cut into individual functional elements, for example, by expanding a dicing tape attached to the second surface 11b of the object 11.

Note that, in the first example of the laser processing method, the laser light L may be incident from the first surface 11a side of the object 11, or the laser light L may be incident from the second surface 11b side of the object 11. In addition, a row of modified regions 12 may be formed inside the object 11 along the line A, or three or more rows of modified regions 12 aligned in the thickness direction of the object 11 may be formed inside the object 11 along the line A. In a case where a plurality of rows of modified regions 12 aligned in the thickness direction of the object 11 are formed inside the object 11 along the line A, the laser light L may be modulated by the spatial light modulator 7 to have a plurality of the converging spots C, and a plurality of rows of modified regions 12 may be formed inside the object 11 along the line A by scanning with the laser light L (relative movement of the laser light L along the line A) which is performed once. In addition, during laser processing, the dicing tape may be attached to the first surface 11a or the second surface 11b opposite to the surface to which the laser light L is incident, or the dicing tape that is transparent to the laser light L may be attached to the first surface 11a or the second surface 11b to which the laser light L is incident. In addition, after the laser processing and before the dicing tape is expanded, the second surface 11b of the object 11 may be ground to make the object 11 thin. At that time, the modified region 12 formed in the object 11 may be removed.

In addition, in the first example of the laser processing method, when forming the modified region 12 (hereinafter, referred to as “first modified region”) close to a surface on an emission side of the laser light L (the second surface 11b in the example illustrated in FIG. 21), the first modified region is formed so that the fracture 13 does not reach the surface on the emission side of the laser light L from the first modified region, and when forming the modified region 12 (hereinafter, referred to as “second modified region”) between the first modified region and a surface on an incident side of the laser light L (the first surface 11a in the example illustrated in FIG. 21), fractures 13 may be connected between the first modified region and the second modified region, and the fractures 13 are allowed to reach the surface on the emission side of the laser light L from the first modified region (hereinafter, referred to as “leaked light damage suppression processing”). In this case, when forming the first modified region, it is preferable that the control unit 6 causes the spatial light modulator 7 to display a modulation pattern including the trefoil aberration pattern so that the first extension portion 91 is located on the line A, the second extension portion 92 is located on one side with respect to the line A, and the third extension portion 93 is located on the other side with respect to the line A, and when forming the second modified region, the control unit 6 causes the spatial light modulator 7 to display a modulation pattern that does not include the trefoil aberration pattern (or a modulation pattern including a trefoil aberration pattern with a weaker trefoil aberration intensity as compared with when forming the first modified region). According to the laser processing method, scattering of the leaked light of the laser light L is suppressed when forming the first modified region, and thus a damage caused by the leaked light on the surface on the emission side of the laser light L can be suppressed. In addition, the quality of an end surface can be improved (that is, unevenness of the cut-out surface can be reduced), and such an effect can be further improved by suppressing twist hackles by using the modulation pattern including the trefoil aberration pattern.

Note that, When forming the first modified region, when the control unit 6 causes the spatial light modulator 7 to display the modulation pattern including the trefoil aberration pattern so that the first extension portion 91 is located on line A, the second extension portion 92 is located on one side with respect to the line A, the third extension portion 93 is located on the other side with respect to the line A, the first extension portion 91 is located on a front side of the direction in which the converging spot C is moved relatively along the line A, and the second extension portion 92 and the third extension portion 93 are located on a rear side of the direction, it is possible to more reliably prevent the fracture 13 from reaching the surface on the emission side of the laser light L from the first modified region.

The above-described findings are applicable to a case where “at least one row of first modified regions” and “at least one row of second modified regions” aligned in the thickness direction of the object 11 are formed inside the object 11 along the line A. In this case, the number of rows of the first modified regions and the number of rows of the second modified regions may be the same as or different from each other.

When forming a plurality of rows of first modified regions aligned in the thickness direction of the object 11 along the line A inside the object 11, in order to shorten time required for laser processing (that is, for so-called tact-up), the laser light L may be modulated by the spatial light modulator 7 to have a plurality of converging spots C, and the plurality of rows of first modified regions may be formed inside the object 11 along the line A by scanning with the laser light L which is performed once. Even in this case, the control unit 6 causes the spatial light modulator 7 to display the modulation pattern including the trefoil aberration pattern so that the first extension portion 91 is located on the line A, the second extension portion 92 is located on one side with respect to the line A, and the third extension portion 93 is located on the other side with respect to the line A. Alternatively, the control unit 6 causes the spatial light modulator 7 to display the modulation pattern including the trefoil aberration pattern so that the first extension portion 91 is located on the line A, the second extension portion 92 is located on one side with respect to the line A, the third extension portion 93 is located on the other side with respect to the line A, the first extension portion 91 is located on a front side of the direction in which the converging spot C is moved relatively along the line A, and the second extension portion 92 and the third extension portion 93 are located on a rear side of the direction. Of course, each of the plurality of rows of first modified regions may be formed inside the object 11 along the line A by each time of scanning with the laser light L which is performed a plurality of times. Note that, even when the plurality of rows of first modified regions are formed inside the object 11 along the line A by scanning with the laser light L which is performed once, and when each of the plurality of rows of first modified regions are formed inside the object 11 along the line A by each time of scanning with the laser light L which is performed a plurality of times, it is preferable that the fractures extending from each of the plurality of rows of first modified regions are not connected to each other.

In addition, in a case of forming a plurality of rows of second modified regions aligned in the thickness direction of the object 11 inside the object 11 along the line A, the laser light L may be modulated by the spatial light modulator 7 to have a plurality of converging spots C for tack-up, and the plurality of rows of second modified regions may be formed inside the object 11 along the line A by scanning with the laser light L which is performed once. Of course, in a case of forming the plurality of rows of second modified regions aligned in the thickness direction of the object 11 inside the object 11 along the line A, each of the plurality of rows of second modified regions may be formed inside the object 11 along the line A by each time of scanning with the laser light L which is performed a plurality of times. Note that, it is preferable that fractures extending from each of the plurality of rows of second modified regions are connected to each other both in a case where the plurality of rows of second modified regions are formed inside the object 11 along the line A by scanning with the laser light L which is performed once and in a case where each of the plurality of rows of second modified regions is formed inside the object 11 along the line A by each time of scanning with the laser light L which is performed a plurality of times.

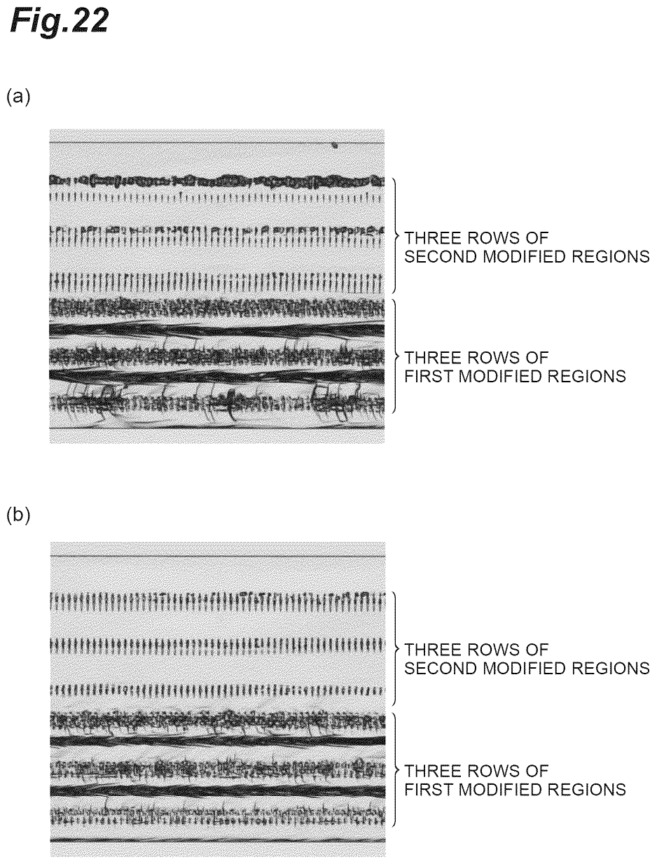

FIG. 22 is a view illustrating an example of the cut-out surface of the object 11 by the leaked light damage suppression processing. The example of the cut-out surface illustrated in (a) and (b) in FIG. 22 was obtained by forming “three rows of first modified regions” and “three rows of second modified regions” aligned in the thickness direction of the object 11 along the line A inside the object 11. In both (a) and (b) in FIG. 22, three rows of first modified regions were formed inside the object 11 along the line A by one scan of the laser light L, and then three rows of second modified regions were formed inside the object 11 along the line A by one scan of the laser light L. In (a) in FIG. 22, when forming the three rows of first modified regions, the spatial light modulator 7 was caused to display a modulation pattern not including a trefoil aberration pattern. In (b) in FIG. 22, when forming three rows of first modified regions, the spatial light modulator 7 was caused to display the modulation pattern including the trefoil aberration pattern so that the first extension portion 91 is located on the line A, the second extension portion 92 is located on one side with respect to the line A, the third extension portion 93 is located on the other side with respect to the line A, the first extension portion 91 is located on a front side of the direction in which the converging spot C is moved relatively along the line A, and the second extension portion 92 and the third extension portion 93 are located on a rear side of the direction. As a result, in (a) in FIG. 22, in a region where the three rows of first modified regions are formed, twist hackles were generated, and extension of the fractures was not stable. On the other hand, in (b) in FIG. 22, in a region where three rows of first modified regions are formed, generation of twist hackles was suppressed, and extension of the fractures was stable.

### Second Example of Laser Processing Method

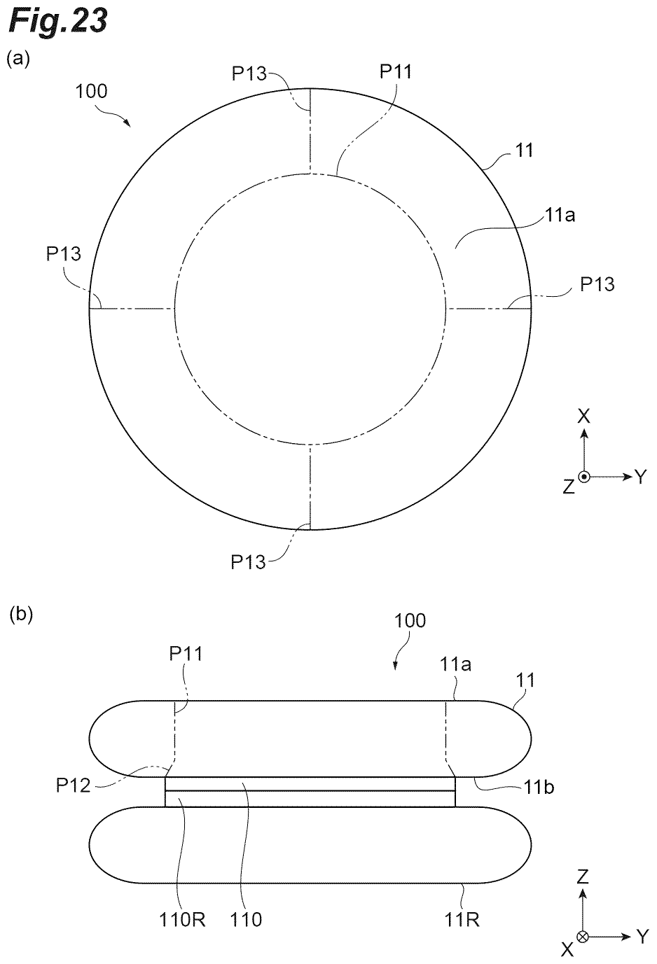

(a) and (b) in FIG. 23 are views illustrating an object 100 to which a second example of the laser processing method is applied. As illustrated in (a) and (b) of in FIG. 23, the object 100 includes an object 11 and an object 11R which is a member separate from the object 11. Each of the objects 11 and 11R is, for example, a silicon wafer. A device layer 110 including a plurality of functional elements (not illustrated) is formed on a second surface 11b of the object 11. A device layer 110R including a plurality of functional elements (not illustrated) is formed on one surface of the object 11R. The device layer 110 and the device layer 110R are bonded to each other.

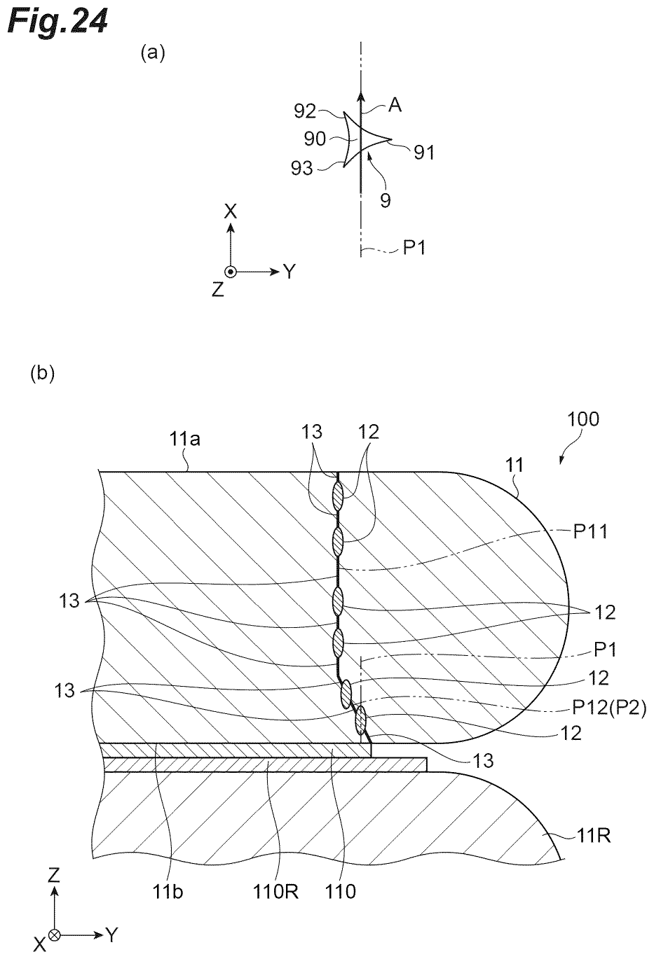

The second example of the laser processing method is carried out in the above-described laser processing apparatus 1. In the second example of the laser processing method, the object 11 illustrated in (a) and (b) in FIG. 23 is cut out along each of a processing plane P11, a processing plane P12, and a plurality of processing planes P13, and an outer edge portion of the object 11 is removed (trimming processing). The processing plane P11 is a cylindrical plane having a center line parallel to the Z-direction. The processing plane P12 is a truncated cone-shaped tapered plane that expands from an end of the processing plane P11 on the device layer 110 side toward an outer edge of the device layer 110R. The plurality of processing planes P13 are planes extending from the processing plane P11 to the outer edge of the object 11. In the second example of the laser processing method, as illustrated in (a) and (b) in FIG. 24, in a state in which the processing plane P12 is aligned with the second plane P2 oblique to the first plane P1 parallel to both the incident direction of the laser light L (Z-direction) and the extension direction of the line A (X-direction), two rows of modified regions 12 aligned in the thickness direction of the object 11 are formed along the line A in a portion along the processing plane P12 within the object 11. Note that, in the second example of the laser processing method, the line A extends circumferentially within the processing plane P12, but when the line A is a curve, the extension direction of the line A represents a tangential direction of the curve.

In the second example of the laser processing method, it is desired to form the modified region 12 in the object 11 along the line A extending within the processing plane P12, and to form the fracture 13 in the object 11 along the second plane P2. In addition, in the second example of the laser processing method, the second plane P2 is oblique so that a region on a side opposite to the incident side of the laser light L is located on an outer side in a direction orthogonal to the first plane P1 (Y-direction).

Therefore, in the second example of the laser processing method, the control unit 6 causes the spatial light modulator 7 to display the modulation pattern including the trefoil aberration pattern so that the first extension portion 91 is located on an outer side of the line A and the second extension portion 92 and the third extension portion 93 are located on an inner side of the line A. At this time, when it is desired to increase the angle between the first plane P1 and the second plane P2, the control unit 6 causes the spatial light modulator 7 to display the modulation pattern including the trefoil aberration pattern with a stronger trefoil aberration intensity. Next, in a state in which the spatial light modulator 7 is caused to display the modulation pattern including the trefoil aberration pattern, the control unit 6 causes the drive unit 4 to drive the support unit 2 so that the converging spot C is moved relatively along the line A. Next, a plurality of the modified regions 12 aligned in the thickness direction of the object 11 are formed along each of the processing plane P11 and the plurality of processing planes P13. After the above processes have been carried out, the outer edge portion of the object 11 is removed, and the first surface 11a of the object 11 is polished to remove a portion where the processing plane P11 was set.

### Operation and Effect

In the laser processing apparatus 1 (and the laser processing method carried out in the laser processing apparatus 1), in a state in which the beam shape 9 of the laser light L at the converging spot C includes the central portion 90, and the first extension portion 91, the second extension portion 92, and the third extension portion 93 extending radially from the central portion 90, and has the highest intensity at the central portion 90, the converging spot C can be moved relatively along the line A set to the object 11. At this time, it is possible to adjust a state of at least one of the modified region 12 and the fracture 13 formed in the object 11 by adjusting a direction of the beam shape 9 with respect to the line A, or the like. As a result, according to the laser processing apparatus 1, it is possible to form an appropriate modified region 12 and an appropriate fracture 13 in the object 11 in correspondence with processing.

In the laser processing apparatus 1, in a case of forming the modified region 12 in the object 11 along the line A, and forming the fracture 13 in the object 11 along the first plane P1 parallel to both an incident direction of the laser light L from the modified region 12 and an extension direction of the line A, the control unit 6 causes the spatial light modulator 7 to display the modulation pattern including the trefoil aberration pattern so that the first extension portion 91 is located on the line A, the second extension portion 92 is located on one side with respect to the line A, and the third extension portion 93 is located on the other side with respect to the line A. According to this, a width of the fracture 13 in the incident direction of the laser light L can be further reduced, for example, as compared with a case where the modulation pattern does not include the trefoil aberration pattern.

In the laser processing apparatus 1, the control unit 6 causes the spatial light modulator 7 to display the modulation pattern including the trefoil aberration pattern so that the first extension portion 91 is located on a front side of a direction in which the converging spot C is moved relatively along the line A, and the second extension portion 92 and the third extension portion 93 are located on a rear side of the direction. According to this, it is possible to reduce not only the width of the fracture 13 in the incident direction of the laser light L but also the width of the modified region 12 in the incident direction of the laser light L. In addition, it is possible to reliably prevent the fracture 13 from meandering with respect to the line A.

In the laser processing apparatus 1, in a case of relatively moving the converging spot C along each of the first line and the second line set to the object 11 as the line A, when a direction in which the converging spot C is moved relatively along the first line and a direction in which the converging spot C is moved relatively along the second line are different from each other, the control unit 6 switches a direction of the modulation pattern including the trefoil aberration pattern so that the first extension portion 91 is located on a front side of the direction in which the converging spot C is moved relatively along each of the first line and the second line, and the second extension portion 92 and the third extension portion 93 are located on a rear side of the direction. According to this, even in a case where a direction in which the converging spot C is moved relatively along the first line and a direction in which the converging spot C is moved relatively along the second line are different from each other, it is possible to easily and reliably realize a state in which the first extension portion 91 is located on a front side of the direction in which the converging spot C is moved relatively along each of the first line and the second line, and the second extension portion 92 and the third extension portion 93 are located on a rear side of the direction.

In the laser processing apparatus 1, the control unit 6 causes the spatial light modulator 7 to display the modulation pattern including the trefoil aberration pattern with a first trefoil aberration intensity in a case where a width of at least one of the modified region 12 and the fracture 13 in the incident direction of the laser light L is set to a first width, and causes the spatial light modulator 7 to display the modulation pattern including the trefoil aberration pattern with a second trefoil aberration intensity stronger than the first trefoil aberration intensity in a case where the width of the at least one of the modified region 12 and the fracture 13 is set to a second width smaller than the first width. According to this, it is possible to set the width of at least one of the modified region 12 and the fracture 13 in the incident direction of the laser light L to an appropriate width in correspondence with processing.

In the laser processing apparatus 1, in a case of forming the modified region 12 in the object 11 along the line A, and forming the fracture 13 in the object 11 along the second plane P2 oblique to the first plane P1 parallel to both the incident direction of the laser light L from the modified region 12 and the extension direction of the line A, when the second plane P2 is oblique so that a region on a side opposite to the incident side of the laser light L is located on one side in a direction orthogonal to the first plane P1, the control unit 6 causes the spatial light modulator 7 to display the modulation pattern including the trefoil aberration pattern so that the first extension portion 91 is located on the one side with respect to the line A, and the second extension portion 92 and the third extension portion 93 are located on the other side with respect to the line A. According to this, it is possible to cause the fracture 13 extending from the modified region 12 to be oblique to a desired side.

In the laser processing apparatus 1, in a case of relatively moving the converging spot C along each of the first line and the second line set to the object 11 as the line A, when a direction in which the converging spot C is moved relatively along the first line and a direction in which the converging spot C is moved relatively along the second line are different from each other, the control unit 6 switches a direction of the modulation pattern including the trefoil aberration pattern so that the first extension portion 91 is located on one side with respect to each of the first line and the second line, and the second extension portion 92 and the third extension portion 93 are located on the other side with respect to each of the first line and the second line. According to this, even in a case where a direction in which the converging spot C is moved relatively along the first line and a direction in which the converging spot C is moved relatively along the second line are different from each other, it is possible to easily and reliably realize a state in which the first extension portion 91 is located on one side with respect to each of the first line and the second line, and the second extension portion 92 and the third extension portion 93 are located on the other side with respect to each of the first line and the second line.

In the laser processing apparatus 1, the control unit 6 causes the spatial light modulator 7 to display the modulation pattern including the trefoil aberration pattern with a first trefoil aberration intensity in a case where an angle between the first plane P1 and the second plane P2 is set to a first angle, and causes the spatial light modulator 7 to display the modulation pattern including the trefoil aberration pattern with a second trefoil aberration intensity stronger than the first trefoil aberration intensity in a case where the angle is set to a second angle larger than the first angle. According to this, it is possible to set an oblique angle of the fracture 13 extending from the modified region 12 to an appropriate angle in correspondence with processing.

### Modification Example

The present disclosure is not limited to the above-described embodiment. For example, the spatial light modulator 7 is not limited to the reflective type, and may be a transmissive type. In addition, the optical system that transfers the image of the laser light L on the modulation surface 7a of the spatial light modulator 7 to the entrance pupil plane 33a of the converging unit 33 is not limited to the 4f lens unit 34 having a pair of lenses 34A and 34B, and may include a first lens system (for example, a cemented lens, three or more lenses, or the like) on the spatial light modulator 7 side and a second lens system (for example, a cemented lens, three or more lenses, or the like) on the converging unit 33 side.

In addition, in the above-described embodiment, the drive unit 4 drives the support unit 2, and the drive unit 5 drives the converging unit 33 by driving the irradiation unit 3, but the drive units of the present disclosure are not limited to such a configuration. As an example, the drive unit 4 may move the support unit 2 in each of the Z-direction, the X-direction, and the Y-direction, and rotate the support unit 2 around an axis parallel to the Z-direction as a rotation axis. Alternatively, the drive unit 5 may move the converging unit 33 in each of the Z-direction, the X-direction, and the Y-direction, and move the converging unit 33 around an axis parallel to the Z-direction as a center line. In other words, the drive units of the present disclosure may drive at least one of the support unit and the converging unit.

In addition, in the above-described embodiment, although the control unit 6 controls the support unit 2, the irradiation unit 3, and the drive units 4 and 5, the control unit of the present disclosure is not limited to such a configuration. The control unit of the present disclosure may be configured to control at least the spatial light modulator and the drive units.

In addition, the laser processing method in which the spatial light modulator 7 is caused to display the modulation pattern including the trefoil aberration pattern so that the first extension portion 91 is located on one side with respect to the line A and the second extension portion 92 and the third extension portion 93 are located on the other side with respect to the line A is also effective in a case of cutting out a wafer into a plurality of truncated cone-shaped chips or cutting out a plurality of truncated cone-shaped wafers from a wafer.

### REFERENCE SIGNS LIST

1: laser processing apparatus, 2: support unit, 4, 5: drive unit, 6: control unit, 7: spatial light modulator, 9: beam shape, 11: object, 12: modified region, 13: fracture, 31: light source, 33: converging unit, 90: central portion, 91: first extension portion, 92: second extension portion, 93: third extension portion, A: line, C: converging spot, L: laser light, P1: first plane, P2: second plane.

1. A laser processing apparatus, comprising:
a support unit configured to support an object;
a light source configured to emit laser light;
a spatial light modulator configured to modulate the laser light emitted from the light source by displaying a modulation pattern;
a converging unit configured to converge the laser light modulated by the spatial light modulator to the object;
a drive unit configured to drive at least one of the support unit and the converging unit; and
a control unit configured to control at least the spatial light modulator and the drive unit,
wherein the control unit,
causes the spatial light modulator to display a modulation pattern including a trefoil aberration pattern so that a beam shape of the laser light at a converging spot of the laser light becomes a beam shape that includes a central portion, and a first extension portion, a second extension portion, and a third extension portion extending radially from the central portion, and has the highest intensity at the central portion, and
causes the drive unit to drive at least one of the support unit and the converging unit so that the converging spot is moved relatively along a line set to the object in a state in which the spatial light modulator is caused to display the modulation pattern including the trefoil aberration pattern.

2. The laser processing apparatus according to claim 1,
wherein in a case of forming a modified region in the object along the line, and forming a fracture in the object from the modified region along a first plane parallel to both an incident direction of the laser light and an extension direction of the line, and
the control unit causes the spatial light modulator to display the modulation pattern including the trefoil aberration pattern so that the first extension portion is located on the line, the second extension portion is located on one side with respect to the line, and the third extension portion is located on the other side with respect to the line.

3. The laser processing apparatus according to claim 2,
wherein the control unit causes the spatial light modulator to display the modulation pattern including the trefoil aberration pattern so that the first extension portion is located on a front side of a direction in which the converging spot is moved relatively along the line, and the second extension portion and the third extension portion are located on a rear side of the direction.

4. The laser processing apparatus according to claim 3,
wherein in a case of relatively moving the converging spot along each of a first line and a second line set to the object as the line, when a direction in which the converging spot is moved relatively along the first line and a direction in which the converging spot is moved relatively along the second line are different from each other, and
the control unit switches a direction of the modulation pattern including the trefoil aberration pattern so that the first extension portion is located on a front side of the direction in which the converging spot is moved relatively along each of the first line and the second line, and the second extension portion and the third extension portion are located on a rear side of the direction.

5. The laser processing apparatus according to claim 2,
wherein the control unit,
causes the spatial light modulator to display the modulation pattern including the trefoil aberration pattern with a first trefoil aberration intensity in a case where a width of at least one of the modified region and the fracture in the incident direction of the laser light is set to a first width, and
causes the spatial light modulator to display the modulation pattern including the trefoil aberration pattern with a second trefoil aberration intensity stronger than the first trefoil aberration intensity in a case where the width of the at least one of the modified region and the fracture is set to a second width smaller than the first width.

6. The laser processing apparatus according to claim 1,
wherein in a case of forming a modified region in the object along the line, and forming a fracture in the object from the modified region along a second plane oblique to a first plane parallel to both an incident direction of the laser light and an extension direction of the line, when the second plane is oblique so that a region on a side opposite to an incident side of the laser light is located on one side in a direction orthogonal to the first plane, and
the control unit causes the spatial light modulator to display the modulation pattern including the trefoil aberration pattern so that the first extension portion is located on the one side with respect to the line, and the second extension portion and the third extension portion are located on the other side with respect to the line.

7. The laser processing apparatus according to claim 6,
wherein in a case of relatively moving the converging spot along each of a first line and a second line set to the object as the line, when a direction in which the converging spot is moved relatively along the first line and a direction in which the converging spot is moved relatively along the second line are different from each other, and
the control unit switches a direction of the modulation pattern including the trefoil aberration pattern so that the first extension portion is located on one side with respect to each of the first line and the second line, and the second extension portion and the third extension portion are located on the other side with respect to each of the first line and the second line.

8. The laser processing apparatus according to claim 6,
wherein the control unit,
causes the spatial light modulator to display the modulation pattern including the trefoil aberration pattern with a first trefoil aberration intensity in a case where an angle between the first plane and the second plane is set to a first angle, and
causes the spatial light modulator to display the modulation pattern including the trefoil aberration pattern with a second trefoil aberration intensity stronger than the first trefoil aberration intensity in a case where the angle is set to a second angle larger than the first angle.

9. A laser processing method that is carried out in a laser processing apparatus including a support unit configured to support an object, a light source configured to emit laser light, a spatial light modulator configured to modulate the laser light emitted from the light source by displaying a modulation pattern, a converging unit configured to converge the laser light modulated by the spatial light modulator to the object, and a drive unit configured to drive at least one of the support unit and the converging unit, the method comprising:
a process of causing the spatial light modulator to display a modulation pattern including a trefoil aberration pattern so that a beam shape of the laser light at a converging spot of the laser light becomes a beam shape that includes a central portion, and a first extension portion, a second extension portion, and a third extension portion extending radially from the central portion, and has the highest intensity at the central portion; and
a process of causing the drive unit to drive at least one of the support unit and the converging unit so that the converging spot is moved relatively along a line set to the object in a state in which the spatial light modulator is caused to display the modulation pattern including the trefoil aberration pattern.
